(19) United States
(12) Patent Application Publication
(10) Pub. No.: US 2010/0221646 A1
(43) Pub. Date: Sep. 2, 2010

(54) HOLOGRAPHIC RECORDING MEDIUM

(75) Inventors: Yoshiaki KAWAMONZEN, Tokyo (JP); Kazuki Matsumoto, Kanagawa-ken (JP); Rumiko Hayase, Kanagawa-ken (JP); Norikatsu Sasao, Tokyo (JP); Masahiro Kanamaru, Kanagawa-ken (JP); Masaya Terai, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/696,537

(22) Filed: Jan. 29, 2010

(30) Foreign Application Priority Data
Feb. 13, 2009 (JP) 2009-030922

(51) Int. Cl. G03F 7/20

(52) U.S. Cl. 430/2

(57) ABSTRACT

A holographic recording medium includes a recording layer. The recording layer includes a framework being expressed with the following general formula (1),

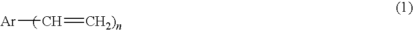

In the above formula (1), Ar represents a substituted or unsubstituted group selected from benzothiophene group, naphthothiophene group, dibenzothiophene group, thienothiophene group, dithienobenzene group, benzothiazole group, naphthothiazole group, benzoisothiazole group, naphthoisothiazole group, phenothiazine group, phenoxathiin group, dithianaphthalene group, thianthrene group, thioxanthene group, and bithiophene group. In addition, n is an integer from 1 to 4.

### CROSS REFERENCE TO RELATED APPLICATION

This application is based upon and claims the benefit of priority from the prior Japanese Patent Application No. 2009-030922, filed on Feb. 13, 2009, the entire contents of which are incorporated herein by reference.

### FIELD OF THE INVENTION

The present invention relates to the holographic recording medium capable of performing high density recording.

### DESCRIPTION OF THE BACKGROUND

A holographic memory which records information as a hologram is now attracting many attentions as a next-generation recording medium enabling a high-capacity recording. As a photosensitive composition for the holographic recording, it is known to employ a composition made of, as main components, a radical polymerizable monomer, a thermoplastic binder resin, a photo-radical polymerization initiator and a sensitizing dye. The above-mentioned photosensitive composition for a holographic recording is formed into a film-shape to be a recording layer onto which information is recorded with an interference exposure.

When the recording layer has been subjected to the interference exposure, the regions thereof which have been strongly irradiated with light are allowed to undergo the polymerization reaction of the radical polymerizable monomer. The radical polymerizable monomer diffuses from the regions where the intensity of exposure beam is weak to the regions where the intensity of exposure beam is strong, thereby generating a gradient of concentration thereof in the recording layer. That is, depending on the intensity of the interference beam, a difference in the concentration of the radical polymerizable monomer occurs, thereby generating a difference in refractive index in the recording layer.

A Japanese laid-open patent application JP-A 2006-3387 (Kokai) discloses a recording medium including a three-dimensional cross-linking polymer matrix (which is also called polymer matrix) with polymerizable monomers dispersed therein.

However, if the hardness of the matrix is too high, it may become impossible to allow the radical polymerizable monomer sufficiently to move, thus making it impossible to bring about a sufficient difference in the refractive index. For this reason, the holographic recording medium to be obtained in this case is limited in a recording capacity and in the modulation of refractive indexes. Furthermore, the recording layer sometimes locally shrinks as a result of the polymerization of the radical polymerizable monomer. In such a case, it may become impossible to accurately reproduce the data that have been recorded therein.

It is required for the refractive index of the radical polymerizable monomer to be high in order to enhance the refractive-index difference of a recording portion. For this reason, it has been attempted to introduce aromatic rings into a polymer matrix in order to raise the refractive index. However, the attempt brings about a decrease in the compatibility of the polymer matrix, thereby causing several problems such as light scattering due to precipitation, noise increase, deterioration of light transmission characteristics due to coloring, etc.

### SUMMARY OF THE INVENTION

According to a first aspect of the invention, a holographic recording medium includes a recording layer. The recording layer includes a framework being expressed with the following general formula (1),

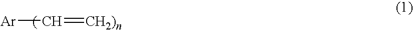

In the above formula (1), Ar represents a substituted or unsubstituted group selected from benzothiophene group, naphthothiophene group, dibenzothiophene group, thienothiophene group, dithienobenzene group, benzothiazole group, naphthothiazole group, benzoisothiazole group, naphthoisothiazole group, phenothiazine group, phenoxathiin group, dithianaphthalene group, thianthrene group, thioxanthene group, and bithiophene group. In addition, n is an integer from 1 to 4.

### BRIEF DESCRIPTION OF DRAWINGS

The accompanying drawings, which are incorporated in and constitute a part of this specification, illustrate embodiments of the invention and together with the description, serve to explain the principles of the invention.

FIG. 1 is a sectional view of a holographic recording medium using a holographic recording material according to an embodiment of the invention.

FIG. 2 is a view of a recording/reproducing system employing the holographic recording medium according to the embodiment of the invention.

FIG. 3 is a view showing a reflection type holographic recording medium using a holographic recording material according to the embodiment of the invention.

FIG. 4 is a schematic view showing a holographic recording/reproducing system using the reflection type holographic recording medium.

FIG. 5 is a table listing synthesized compounds and synthesizing methods thereof.

FIG. 6 shows chemical structural formulas of the compounds listed in the table of FIG. 5.

FIG. 7 is a table showing evaluation results for examples 1 to 12 of the holographic recording medium according to the embodiment of the invention.

FIG. 8 is a table showing evaluation results for examples 13 to 24 of the holographic recording medium according to the embodiment of the invention.

FIG. 9 is a table showing evaluation results for examples 25 to 36 of the holographic recording medium according to the embodiment of the invention.

FIG. 10 is a table showing evaluation results for examples 37 to 40 of the holographic recording medium according to the embodiment of the invention.

### DETAILED DESCRIPTION OF THE EMBODIMENTS

Embodiments of the present invention are described below with reference to drawings.

A holographic recording medium according to an embodiment of the present invention includes a polymer matrix, a radical polymerizable monomer, and a photo-radical polymerization initiator.

The polymer matrix, the radical polymerizable monomer, and the photo-radical polymerization initiator are described below.

### Polymer Matrix

The polymer matrix is employed to disperse the radical polymerizable monomer, and means a polymer to hold the monomer or the polymerization initiator associated with recording or storing. The polymer matrix is used to enhance a characteristic of film-coating or film strength, and a performance of the holographic recording.

The following two methods are mentioned as methods for synthesizing the polymer matrix. One is to make epoxy monomers react with a catalyst. The other is to add amine or thiol to an epoxy compound.

First, the synthesizing method to make epoxy monomers react with a catalyst is described.

When an epoxy monomer is synthesized with a catalytic reaction, there is no restriction in particular for the polymer matrix to be appropriately selected according to the purpose thereof. It is preferable that the polymer matrix is a heat-curable matrix. Examples of the polymer matrix include multifunctional isocyanate, urethane matrix formed from multifunctional alcohol, epoxy compounds formed from oxirane compounds, oxetane resin made from oxetane compounds, melamine compounds, formalin compounds, ester compounds such as (meth)acrylic acid, itaconic acid, etc., and amid compounds. Among them, the epoxy compounds made from the oxirane compounds are particularly preferable.

As the polymer matrix, the epoxy compound with a structure expressed with the following general formula (2) is employed.

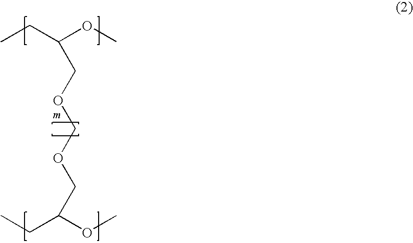

In the above general formula (2), m denotes an integer from 3 to 16.

The epoxy compound has no highly polar substituent group such as an amino group or amide in the skeleton thereof. For this reason, the radical polymerizable monomer can freely migrate in a three-dimensional cross-linking polymer matrix without being affected by the polarity thereof.

Furthermore, the epoxy compound is formed of an alkyl group and an ethylene oxide skeleton. Since these skeletons are flexible, the matrix itself can also move flexibly in response to the movement of the radical polymerizable monomer. This further prompts the radical polymerizable monomer to migrate in the three-dimensional cross-linking polymer matrix. The above prompt is enhanced for m ranging from 6 to 12, and is more enhanced for m ranging from 8 to 12.

In addition, it is preferable that an aromatic ring is not included in the three-dimensional cross-linking polymer matrix expressed with the above-mentioned general formula (2). If the aromatic ring is included in the polymer matrix, the flexibility of the skeleton would be degraded, thereby possibly obstructing the migration of the radical polymerizable monomer. Furthermore, the polarity of the polymer matrix changes to enhance the affinity of the polymer matrix with the radical polymerizable compound, thereby obstructing the migration of the radical polymerizable monomer. Then, in order to avoid the problems including the absorption of light by the aromatic ring, the reduction of voids in the polymer matrix due to the orientation of the aromatic ring, and the increase in the refractive index of the polymer matrix, it is desirable that the aromatic ring does not exist in the skeleton of the polymer matrix.

The three-dimensional cross-linking polymer matrix expressed with the above-mentioned general formula (2) can be synthesized through the cationic polymerization of epoxy monomer. As the epoxy monomer, it is possible to employ, for example, glycidyl ether. More specifically, examples of the epoxy monomer include ethyleneglycol diglycidyl ether, 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, 1,12-dodecanediol diglycidyl ether, etc.

When the migrating easiness of the radical polymerizable monomer in the polymer matrix is taken into consideration, the epoxy monomer is preferably selected from the compounds expressed with the following general formula (3).

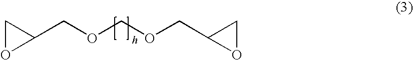

In the above general formula (3), h is an integer from 8 to 12.

Examples of the compounds expressed with the general formula (3) include 1,8-octane dioldiglycidyl ether, 1,10-decane dioldiglycidyl ether, and 1,12-dodecane dioldiglycidyl ether.

### Synthesis of Epoxy Monomer

A metal complex and alkyl silanol are employed both acting as a catalyst to cationically polymerize the epoxy monomer.

As the metal complex, it is possible to employ the compounds expressed with the following general formulas (4), (5) and (6):

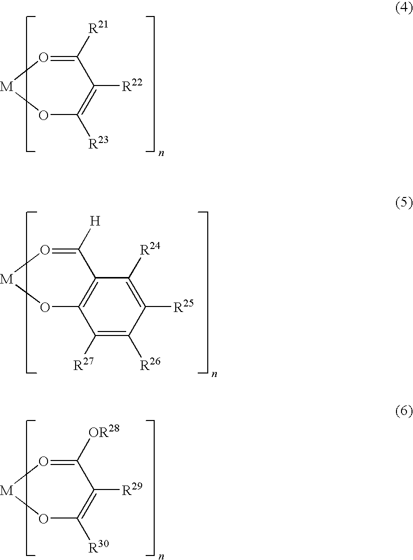

In the above general formulas (4), (5) and (6),

M is selected from the group consisting of Al, Ti, Cr, Mn, Fe, Co, Ni, Cu, Zr, Zn, Ba, Ca, Ce, Pb, Mg, Sn and V;
R²¹, R²² and R²³ may be the same or different, and are individually hydrogen atom, substituted or unsubstituted alkyl group having 1 to 10 carbon atoms;
R²⁴, R²⁵, R²⁶ and R²⁷ may be the same or different and are individually hydrogen atom, substituted or unsubstituted alkyl group having 1 to 10 carbon atoms; and
R²⁸, R²⁹ and R³⁰ may be the same or different and are individually hydrogen atom, substituted or unsubstituted alkyl group having 1 to 10 carbon atoms.

When the compatibility of the metal complex with the three-dimensional cross-linking polymer matrix and the catalytic power thereof are taken into consideration,

the M in these general formulas (4), (5) and (6) is preferably selected from Al and Zr; and
R²¹ to R³⁰ is preferably selected from alkyl acetate such as acetyl acetone, methylacetyl acetate, ethylacetyl acetate, propylacetyl acetate, etc.
Among them, the most preferable metal complex is aluminum tris (ethylacetyl acetate).

As the alkyl silanol, it is possible to employ compounds expressed with the following general formula (7).

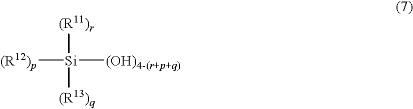

In the above general formula (7),

R¹¹, R¹² and R¹³ may be the same or different, and are individually substituted or unsubstituted alkyl group having 1 to 30 carbon atoms, substituted or unsubstituted aromatic group having 6 to 30 carbon atoms, or substituted or unsubstituted aromatic heterocyclic group having 3 to 30 carbon atoms; and
p, q and r are individually an integer of 0 to 3 with a proviso that p+q+r is 3 or less.

As examples of the alkyl group to be introduced as R¹¹, R¹² and R¹³ into the general formula (7), they include, for example, methyl, ethyl, propyl, butyl, pentyl, hexyl, etc. As examples of the aromatic group to be introduced as R¹¹, R¹² and R¹³ into the general formula (7), they include, for example, phenyl, naphthyl, tolyl, xylyl, cumenyl, mesityl, etc. As examples of the aromatic heterocyclic group to be introduced as R¹¹, R¹² and R¹³ into the general formula (7), they include, for example, pyridyl, quinolyl, etc. At least one of the hydrogen atoms in these alkyl group, aromatic group and aromatic heterocyclic group may be substituted by a substituent group such as halogen atoms, etc.

More specific examples of alkyl silanol include diphenyl disilanol, triphenyl silanol, trimethyl silanol, triethyl silanol, diphenyl silanediol, dimethyl silanediol, diethyl silanediol, phenyl silanediol, methyl silanetriol, ethyl silanetriol, etc. When the compatibility of alkyl silanol with the three-dimensional cross-linking polymer matrix and the catalytic power thereof are taken into consideration, the employment of diphenyl disilanol or triphenyl silanol is preferable as the alkyl silanol.

The phenolic compound expressed with the following general formula (8) can be employed as a compound having almost the same effects as the alkyl silanol expressed with the above-mentioned general formula (7).

R¹⁴—Ar—OH (8)

In the above general formula (8), R¹⁴ is substituted or unsubstituted alkyl group having 1 to 30 carbon atoms, or substituted aromatic group having 6 to 30 carbon atoms; and Ar is substituted or unsubstituted aromatic group having 3 to 30 carbon atoms.

As examples of the alkyl group to be introduced as R¹⁴ into the general formula (8), they include, for example, methyl, ethyl, propyl, butyl, pentyl, hexyl, trifluoromethyl, pentafluoroethyl, etc. At least one of the hydrogen atoms in the alkyl group may be is substituted by a substituent group such as a halogen atom, etc.

As examples of the substituted aromatic group that can be introduced as R¹⁴ into the general formula (8), they include, for example, HO(C₆H₄)SO₂—, HO(C₆H₄)C(CH₃)₂—, HO(C₆H₄)CH₂—, etc.

As examples of the aromatic group that can be introduced as Ar into the general formula (3), they include, for example, phenyl, naphthyl, tolyl, xylyl, cumenyl, mesityl, etc. At least one of the hydrogen atoms in the aromatic group may be substituted by the above-mentioned substituent group.

As examples of the phenolic compound expressed with the above-mentioned general formula (8), they include HO(C₆H₄)SO₂(C₆H₄)OH, HO(C₆H₄)CH₂(C₆H₄)OH, and HO(C₆H)₄C(CH₃)₂(C₆H₄)OH, CF₃(C₆H₄)OH, CF₃CF₂(C₆H₄) OH, etc. When the compatibility of the phenolic compound with the three-dimensional cross-linking polymer matrix and the catalytic power thereof are taken into consideration, the employment of CF₃(C₆H₄)OH and HO(C₆H₄)SO₂(C₆H₄)OH is preferable as the phenolic compound.

A cationic polymerization catalyst which is composed of a combination of the alkyl silanol expressed with the above-mentioned general formula (7) with the metal complex expressed with any one of the above-mentioned general formulas (4), (5) and (6) is capable of promoting the polymerization reaction of the radical polymerizable compound at room temperature (25° C.). Therefore, it is possible to form the three-dimensional cross-linking polymer matrix without any application of heat history to the radical polymerizable compound and to the photo-radical polymerization initiator.

Even when the alkyl silanol is replaced by the phenolic compound expressed with the above-mentioned general formula (8), almost the same effects as described above can be obtained.

Moreover, the catalytic components such as the alkyl silanol expressed with the above-mentioned general formula (7), the phenolic compound expressed with the above-mentioned general formula (8) and the metal complex expressed with any one of the above-mentioned general formulas (4), (5) and (6) are enabled to exist in the three-dimensional cross-linking polymer matrix without reacting with this polymer matrix obtained through the polymerization. Furthermore, no ionic impurities can be generated.

When a predetermined region of the recording layer including the three-dimensional cross-linking polymer matrix, the radical polymerizable monomer and the photo-radical polymerization initiator is irradiated with light to perform an exposure of the recording layer, the radical polymerizable monomer is caused to migrate to the exposed region. The space created by this migration of the radical polymerizable monomer is then occupied by the catalytic components existing in the polymer matrix. As a result, the change in refractive index is more enhanced.

Even if a reaction between the catalytic components happens, there would not be raised any problem. It is more preferable to employ the phenolic compound expressed with the general formula (8) rather than the alkyl silanol expressed with the general formula (7), as rapid reactions can be prevented by employing the phenolic compound to hence retard rates of the reaction. This results in easiness to control the shrinkage and strain of the recording medium.

Furthermore, these catalytic components do not generate decomposition products such as alcohol or impurities. Water is not required to exist in the recording medium when effecting the catalytic action. It is, therefore, possible to employ a recording medium in a stable dry condition.

The catalytic components, such as the metal complex and alkyl silanol described above, act to strengthen the adhesion between the substrate sustaining the recording medium and the recording layer. When a molecule highly polarized therein such as the metal complex co-exists with the hydroxyl group of silanol in the recording layer, the adhesion of the recording layer to various kinds of substrates such as those made of glass, polycarbonate, acrylic resin, polyethylene terephthalate (PET), etc., can be enhanced.

When the adhesion of the recording layer to the transparent substrate is enhanced, it is possible to prevent peel-off of the recording layer even if volumetric shrinkage or expansion occurs at a tiny exposed region or unexposed region when writing information with interference light wave. Since the information thus recorded can be retained without any distortion, it is possible to further enhance the recording performance. Furthermore, the metal complex and alkyl silanol exist in the polymer matrix without deactivation.

For this reason, the information thus written can be fixed through the post-baking of the recording medium, thus allowing it to prevent the information from changing with time. When the recording medium is subjected to exposure to interference light wave, the radical polymerizable monomer polymerizes to increase the density of the exposed region, thus heightening the refractive index. On the other hand, at the unexposed region, the density thereof is reduced as a result of the migration of the radical polymerizable monomer therefrom, thus lowering the refractive index. The radical polymerizable monomer in this case can be easier to migrate as the polymer matrix of the recording medium is lower in density. That is, as the crosslink density of the three-dimensional cross-linking polymer matrix becomes lower, the radical polymerizable monomer can be easier to migrate, thus providing a recording medium with higher sensitivity.

However, in the three-dimensional cross-linking polymer matrix with a low crosslink density, the migrated polymerizable monomer or the polymer thereof tends to migrate into an unexposed region which is spatially low in density. Therefore, the crosslink density of the polymer matrix is preferably decreased so as to allow the radical polymerizable monomer to easily migrate when recording information through the exposure of the recording layer to an interference light wave. After the information has been written in the recording layer, however, when the information is desired to be fixed, it will be effective to enhance the crosslink density of the polymer matrix by post-baking. Since the recording medium according to the embodiment is allowed to increase the crosslink density of the polymer matrix by post-baking, the recording performance of the recording medium can be enhanced.

The post-baking is preferably performed at a temperature ranging from 40° C. to 100° C. If the temperature of post-baking is lower than 40° C., it may become difficult to enhance the crosslink density of the polymer matrix. On the other hand, if the temperature of post-baking exceeds 100° C., the molecular motion of the polymer matrix would be activated, thereby possibly making it impossible to read out the recorded information.

As mentioned above, when recording information with an interference light wave, the density of the recording layer increases at the exposed region, while the density of unexposed region is reduced. Owing to a difference in density of the recording layer, the catalytic components such as the metal complex and alkyl silanol migrate from the exposed region to the unexposed region. This migration of these catalytic components promotes the migrating of the radical polymerizable monomer to the exposed region. Further, the catalytic components that have been migrated to the unexposed region of the recording layer act to lower the refractive index of the unexposed region thereof.

The three-dimensional cross-linking polymer matrix (a cured product of epoxy resin) that has been polymerized using the metal complex and alkyl silanol as catalysts is transparent to light ranging from visible light to ultraviolet, and has an optimal hardness. Namely, since the polymer matrix is transparent to an exposure wavelength, the absorption of light by the photo-radical polymerization initiator cannot be obstructed, thereby allowing it to obtain a three-dimensional cross-linking polymer matrix having a suitable degree of hardness for allowing the radical polymerizable monomer to appropriately diffuse therein. As a result, it is now possible to manufacture a holographic recording medium which is excellent in sensitivity and diffraction efficiency. Furthermore, since the three-dimensional cross-linking polymer matrix has a suitable degree of hardness, it is possible to inhibit the recording layer from being shrunk at the region where the polymerization of the radical polymerizable monomer has taken place.

The employment of the above-mentioned epoxy monomer in the formation of the three-dimensional cross-linking polymer matrix is advantageous in the following respects. Namely, when the above-mentioned epoxy monomer is employed, it is possible to eliminate any possibility of obstructing the migration of the radical polymerizable monomer to be generated on the occasion of exposure. The reasons for this can be explained as follows. First of all, it is possible to secure a sufficient space for allowing the radical polymerizable monomer to migrate in the three-dimensional cross-linking polymer matrix. There is little possibility of locally enhancing the crosslink density. Furthermore, since the polarity of the polymer matrix is low, the migration of the radical polymerizable monomer cannot be obstructed. Therefore, it is now possible to perform excellent write-in of hologram.

In order to increase the diffraction efficiency of the recording medium, the compound expressed with the following general formula (9) may be incorporated into the recording layer.

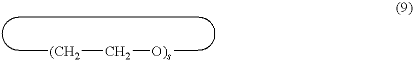

In the above-mentioned general formulas (9), s is an integer of 3 to 30.

When the migrating velocity of this compound in the polymer matrix is taken into consideration, s is preferably confined to not more than 6. The general formula (9) is formed of an ethylene oxide skeleton and is excellent in affinity with the polymer matrix including an alkyl chain and an ethylene oxide skeleton. Thereby, it is possible to create a homogeneous medium without generating a phase separation. Furthermore, since this compound expressed with the general formula (9) is formed of a cyclic structure, it has no terminal polar group and maintains a constant cyclic structure, thereby allowing it to diffuse very uniformly and swiftly.

As described above, the three-dimensional cross-linking polymer matrix expressed with the above-mentioned general formula (1) can be produced through the radical polymerization of the epoxy monomer expressed with the above-mentioned general formula (9). On the occasion of the radical polymerization, a polymer component expressed with the following general formula (10) may be occasionally created.

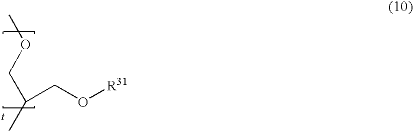

In the above-mentioned general formulas (10), R³¹ is unsubstituted alkyl group having 1 to 12 carbon atoms, methoxyethyl group or methoxyethoxyethyl group.

When the three-dimensional cross-linking polymer matrix includes this skeleton, the flexibility thereof can be further enhanced. Since the skeleton expressed with the general formula (10) also has high affinity with the materials of the three-dimensional cross-linking polymer matrix, it is possible to maintain a uniform recording medium.

In the above, the synthesizing method of the polymer matrix using the catalysts has been described.

The synthesizing method of the polymer by adding amine or thiol into the epoxy compound is described below.

As this epoxy compound, for example, 1,4-butanediol diglycidyl ether, 1,6-hexanediol diglycidyl ether, diethylene glycol diglycidyl ether, polyethylene glycol diglycidyl ether, polypropylene glycol diglycidyl ether, neopentyl glycol diglycidyl ether, diepoxy octane, resorcinol diglycidyl ether, diglycidyl ether of bisphenol A, diglycidyl ether of bisphenol F, 3,4-epoxy cyclohexenyl methyl-3′,4′-epoxy cyclohexene carboxylate, polydimethylsiloxane of an end of epoxy propoxy propyl, etc. are employed.

As the compound which cures an epoxy compound, i.e., a curing agent, amine, phenol, organic anhydride and mercaptan compound and amide, which are known as an epoxy curing agent for epoxy, are mentioned. More specifically, examples of the amine include ethylene diamine, diethylene triamine, triethylene tetramine, tetraethylene pentamine, pentaethylene hexamine, hexamethylene diamine, menthene diamine, isophorone diamine, bis(4-amino-3-methyldicyclohexyl)methane, bis(aminomethyl)cyclohexane, N-aminoethyl piperazine, m-xylylene diamine, 1,3-diaminopropane, 1,4-diaminobutane, trimethylhexamethylene diamine, iminobispropyl amine, bis(hexamethylene)triamine, 1,3,6-trisaminomethylhexane, dimethylaminopropyl amine, aminoethyl ethanol amine, tri(methylamino) hexane, m-phenylene diamine, p-phenylene diamine, diaminodiphenyl methane, diaminodiphenyl sulfone, 3,3′-dietheyl-4,4′-diaminodiphenyl methane, maleic anhydride, succinic anhydride, tetrahydro phthalic anhydride, methyl cyclohexene-dicarboxylic anhydride, methylnadic anhydride, hexahydro phthalic anhydride, methylhexahydrophthalic anhydride, methylcyclohexene tetracarboxylic anhydride, phthalic anhydride, trimellitic anhydride, benzophenone tetracarboxylic anhydride, ethyleneglycol bis(anhydrotrimellitate), phenol novolac resin, cresol novolac resin, polyvinyl phenol, terpene phenol resin, polyamide resin, etc. are employed. The epoxy compound preferably becomes liquid at 20° C. or higher. Also, the epoxy compound may preferably dissolve 2 wt % or more of a radical polymerizable monomer, and more preferably 5 wt % or more thereof.

Since aliphatic primary amine can be cured quickly at room temperature, aliphatic primary amine can be preferably employed as amine. For example, diethylene triamine, triethylene tetramine, tetraethylene pentamine, pentaethylene hexamine and iminobispropyl amine are employed. The mixing ratio of these amines relative to the oxirane of 1,6-hexanediol diglycidyl ether or diethylene glycol diglycidyl ether is preferably confined to such that the NH— of amine is 0.6 time to twice as high as the equivalent weight. When this mixing ratio of these amines is less than 0.6 time or more than twice of the equivalent weight, the resolution may be deteriorated.

Alternatively, a curing catalyst may be added if needed. As the curing catalyst, a basic catalyst which is known as an epoxy curing catalyst is employed. For example, tertiary amine, an organic phosphine compound, an imidazole compound and its derivative, etc. are employed. Specifically, triethanolamine, piperidine, dimethyl piperazine, 1,4-diazacyclo(2,2,2) octane (triethyleneamine), pyridine, picoline, dimethylcyclohexylamine, dimethylhexylamine, benzildimethylamine, 2-(dimethylaminomethyl)phenol, 2,4,6-tris(dimethylamino methyl)phenol, DBU (1 and 8-diazabicyclo(5,4,0 undecene-7)) or the phenol salt thereof, trimethylphosphine, triethyl phosphine, tributylphosphine, triphenylphosphine, tri(p-methylphenyl)phosphine, 2-methyl imidazole, 2,4-dimethylimidazole, 2-ethyl 4-methyl imidazole, 2-phenyl imidazole, 2-phenyl 4-methyl imidazole, 2-hepta-imidazole, etc. are employed. Alternatively, a boron trifluoride amine complex, dicyandiamide, organic acid hydrazide, diaminomaleonitrile and the derivative thereof, melamine and the derivative thereof, and latency catalysts, such as amine imide, may be employed.

Examples of thiol include dithiol, such as 1,3-butanedithiol, 1,4-butanedithiol, 2,3-butanedithiol, 1,2-benzenedithiol, 1,3-benzenedithiol, 1,4-benzenedithiol, 1,10-decanedithiol, 1,2-ethanedithiol, 1,6-hexanedithiol, 1,9-nonanedithiol.

### Radical Polymerizable Monomer

A radical polymerizable monomer is described below. The radical polymerizable monomer serves to record information into a holographic recording medium. Specifically, a polymerization reaction is advanced by adding energies, such as light and heat, to the radical polymerizable monomer. As a result, the concentration gradient of the radical polymerizable monomer is generated, thereby causing a contrast in refractive index in the recording medium. The contrast allows it to record information.

As the radical polymerizable monomer, a sulfur heterocycle containing at least 1 wt % or more of the sulfur heterocycle expressed with the following general formula (1) is employable.

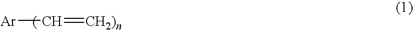

Ar in the above-mentioned general formula (1) represents one of the following groups:

a benzothiophene group;
a naphthothiophene group;
a dibenzothiophene group;
a thienothiophene group;
a dithienobenzene group;
a benzothiazole group;
a naphthothiazole group;
a benzoisothiazole group;
a naphthoisothiazole group;
a phenothiazine group;
a phenoxathiin group;
a dithianaphthalene group;
a thianthrene group;
a thioxanthene group; and
a bithiophene group.
Here, n is an integer from 1 to 4.

Examples of a characteristic group to be introduced into the Ar group include the following groups:

a di-substitution amino group (for example, a dimethylamino group, a diethylamino group, a dibutylamino group, an ethylmethylamino group, a butylmethylamino group, a diamylamino group, a dibenzylamino group, a diphenethylamino group, a diphenylamino group, a ditolylamino group, a dixylylamino group, a methylphenylamino group, a benzylmethylamino group, a hydroxyethyl methylamino group, a hydroxyethylthylamino group, a bishydroxyethylamino group, etc.), a mono-substitution amino group (for example, a methylamino group, an ethylamino group, a propylamino group, an isopropylamino group, a tertiary butylamino group, an anilino group, a phenetidino group, a toluidino group, a xylidino group, a pyridylamino group, a thiazolyl amino group, a benzylamino group, a benzylideneamino group, a hydroxyethylamino group. etc.), a heterocycle-ring amino group (for example, a pyrrolidino group, a piperidino group, a piperazino group, a morpholino group, a 1-pyrrolyl group, 1-pyrazolyl group, a 1-imidazolyl group, a1-triazoryl group, etc.), a acylamino group (for example, a formylamino group, an acetylamino group, a benzoylamino group, a cinnamoylamino group, a pyridine carbonylamino group, a trifluoroacetylamino group, etc.), a sulfonylamino group (for example, a mesylamino group and an ethylsulfonylamino group), a phenylsulfonylamino group, a pyridylsulfonylamino group, a tosylamino group, a taurylamino group, a trifluoromethyl sulfonylamino group, a sulfamoylamino group, a methyl sulfamoyl amino group, a sulfanil amino group, an acetyl sulfanil amino group, etc.), an ammonio group (for example, a trimethylammonio group, an ethyldimethylammonio group, a dimethylphenyl ammonio group, a pyridinio group, a quinolinio group, etc.), an amino group, an oxyamino group (for example, a methoxyamino group and ethoxyamino group, a phenoxyamino group, a pyridyloxyamino group, etc.), a hydroxyamino group, an ureide group, a semicarbazide group, a carbazide group, a di-substitution hydrazino group (for example, a dimethylhydrazino group, a diphenylhydrazino group, a methylphenylhydrazino group, etc.), a mono-substitution hydrazino group (for example, a dimethylhydrazino group, a phenylhydrazino group, a pyridylhydrazino group, a benzylidenehydrazino group, etc.), a hydrazino group, an azo group (for example, a phenylazo group, a pyridylazo group, a thiazolylazo group, etc.), an azoxy group, an amidino group, a cyano group, a cyanate group, a thiocyanato group, a nitro group, a nitroso group, an oxy group (for example, a methoxy group, an ethoxy group, a propoxy group, a butoxy group, a hydroxy ethoxy basis, a phenoxy group, a naphthoxy group, a pyridyloxy group, a thiazolyloxy group, an acetoxy group, etc.), a hydroxy group, a thio group (for example, a methylthio group, an ethyl thio group, and a phenylthio group, a pyridylthio group, a thiazolylthio group, etc.), a mercapto group, a halogen group (a fluoro group, a chloro group, a bromo group, an iodo group), a carboxyl group and its salt, an oxycarbonyl group (for example, a methoxy carbonyl group, a ethoxycarbonyl group, a phenoxycarbonyl group, a pyridyloxycarbonyl group, etc.), an aminocarbonyl group (for example, a carbamoyl group, a methylcarbamoyl group, a phenylcarbamoyl group, a pyridyl carbamoyl group, a carbazoyl group, an allophanoyl group, a oxamoyl group, a succinamoyl group, etc.), a thiocarboxyl group and its salt, a dithiocarboxyl group and its salt, a thiocarbonyl group (for example, a methoxythiocarbonyl group, a methylthiocarbonyl group, a methylthiothiocarbonyl group, etc.), an acyl groups (for example, a formyl group, an acetyl group, a propionyl group, an acrylyl group, a benzoyl group, a cinnamoyl group, a pyridinecarbonyl group, a thiazolecarbonyl group, a trifluoroacetyl group, etc.), a thioacyl group (for example, a thioformyl group, a thioacetyl group, a thiobenzoyl group, a pyridinethiocarbonyl group, etc.), a sulfinic acid group and its salt, a sulfonic group and its salt, a sulfinyl group (for example, a methylsulfinyl group, an ethylsulfinyl group, a phenyl sulfonyl group, etc.), a sulfonyl group (for example, a mesyl group, an ethyl sulfonyl group, a phenyl sulfonyl group, a pyridyl sulfonyl group, a tosyl group, a tauryl group, a trifluoromethylsulfonyl group, a sulfamoyl group, a methyl sulfamoyl group, sulfanilyl group, an acetylsulfanilyl group, etc.), an oxysulfonyl groups (for example, a methoxysulfonyl group, an ethoxysulfonyl group, a phenoxysulfonyl group, an acetaminophenoxysulfonyl group, a pyridyloxysulfonyl group, etc.), a thiosulfonyl group (for example, a methylthiosulfonyl group, a ethylthiosulfonyl group, a phenylthiosulfonyl group, an acetaminophenylthiosulfonyl group, a pyridylthiosulfonyl group, etc.), an aminosulfonyl group (for example, a sulfamoyl group, a methyl sulfamoyl group, a dimethylsulfamoyl group, an ethylsulfamoyl group, a diethylsulfamoyl group, a phenylsulfamoyl group, an acetaminophenylsulfamoyl group, a pyridylsulfamoyl group, etc.), an alkylhalide group (for example, a chloromethyl group, a bromomethyl group, a fluoromethyl group, a dichloromethyl group, a dibromomethyl group, a difluoromethyl group, a trifluoromethyl group, a pentafluoroethyl group, a heptafluoropropyl group, etc.), a polycyanoalkyl groups (tricyanovinyl group, etc.), a hydrocarbon group (for example, an alkyl group, an aryl group, an alkenyl group, an alkynyl group, etc.), a heterocyclic group, an organic silicon group (for example, a silyl group, a disilanyl group, a trimethylsilyl group, triphenylsilyl group, etc.).

Characteristic groups to be introduced as Ar include a chloro group, a bromo group, an iodo group, a thio group, an aryl group, etc. which has a large effect for increasing the refractive index.

As a sulfur-containing heterocyclic compound expressed with a general formula (1), vinylbenzothiophene, vinylnaphthothiophene, vinyldibenzothiophene, vinylthienothiophene, vinyldithienobenzene, vinylbenzothiazole, vinylnaphthothiazole, vinylbenzoisothiazole, vinylnaphthoisothiazole, vinylphenothiazine, vinylphenoxathiin, vinyldithianaphthalene, vinylthianthrene, vinylthioxanthene, vinylbithiophene, vinylbromobenzothiophene, vinylbromobithiophene, etc. are desirable.

Methods to increase the refractive index of a monomer include the following;
a method for introducing many aromatic hydrocarbon groups;
a method for introducing a bromo group or an iodo group; and
a method for introducing an alkylthio group, and an arylthio group.
However, the aromatic hydrocarbon groups are introduced so much to decrease the compatibility thereof with the polymer matrix drastically, thereby causing light scattering or a noise due to precipitation. For example, vinylnaphthalene has low compatibility with the polymer matrix. It is difficult to mix not less than 3 wt % of vinylnaphthalene.

In the radical polymerizable monomer including the sulfur heterocycles expressed with the general formula (1), sulfur allows it to heighten the refractive index of the radical polymerizable monomer, and to enhance the compatibility thereof to the polymer matrix greatly. The radical polymerizable monomer is excellent in preserving stability due to an aromatic ring. That is, the radical polymerizable monomer has a higher glass-transition temperature and an enhanced heat resistance, thereby being hard to thermally oxidize. Therefore, according to the embodiment of the invention, it is possible to provide an excellent radical polymerizable monomer having a high refractive index, a high performance, high compatibility, a high heat resistance, and high environmental stability.

Alternatively, other radical polymerizable monomers may be mixed together with the sulfur heterocycles expressed with the general formula (1). As a mixable compound with an ethylene unsaturated double bond, unsaturated carboxylic acid, unsaturated carboxylic ester, unsaturated carboxylic-acid amide, a vinyl compound, etc. are employed, for example. As the radical polymerizable compound, it is possible to employ compounds having an ethylenic unsaturated double bond. For example, unsaturated carboxylic acid, unsaturated carboxylate, unsaturated carboxylic acid amide and vinyl compounds can be employed as the radical polymerizable compound. Examples of the radical polymerizable compound include acrylic acid, methyl acrylate, ethyl acrylate, propyl acrylate, butyl acrylate, isobutyl acrylate, 2-ethylhexyl acrylate, octyl acrylate, lauryl acrylate, stearyl acrylate, cyclohexyl acrylate, bicyclopentyl acrylate, phenyl acrylate, isobonyl acrylate, adamantyl acrylate, methacrylic acid, methyl methacrylate, propyl methacrylate, butyl methacrylate, phenyl methacrylate, phenoxyethyl acrylate, chlorophenyl acrylate, adamantyl methacrylate, isobonyl methacrylate, N-methyl acrylic amide, N,N-dimethyl acrylic amide, N,N-methylene bisacrylic amide, acryloyl morpholine, vinyl pyridine, styrene, bromostyrene, chlorostyrene, tribromophenyl acrylate, trichlorophenyl acrylate, tribromophenyl methacrylate, trichlorophenyl methacrylate, vinyl benzoate, 3,5-dichlorovinyl benzoate, vinyl naphthalene, vinyl naphthoate, naphthyl methacrylate, naphthyl acrylate, N-phenyl methacryl amide, N-phenyl acryl amide, N-vinyl pyrrolidinone, N-vinyl carbazole, 1-vinyl imidazole, bicyclopentenyl acrylate, 1,6-hexanediol diacrylate, pentaerythritol triacrylate, pentaerythritol tetraacrylate, dipentaerythritol hexaacrylate, diethylene glycol diacrylate, polyethylene glycol diacrylate, polyethylene glycol dimethacrylate, tripropylene glycol diacrylate, propylene glycol trimethacrylate, diallyl phthalate, triallyl trimellitate, etc.

These radical polymerizable monomers are preferably added by 1 to 50 wt % to the whole recording medium. Below 1 wt %, it may become impossible to enhance the refractive index of the recorded area sufficiently. Over 50 wt %, the volume shrinkage thereof may possibly increase, thereby possibly deteriorating the resolution. These radical polymerizable monomers are more preferably added by 3 to 30 wt % to the whole recording medium. Of them, the sulfur heterocycles expressed with the general formula (1) are contained preferably by 1 wt % or more, and more preferably by 5 wt % or more.

### Photo-Radical Polymerization Initiator

A photo-radical polymerization initiator is described below. The photo-radical polymerization initiator serves to initiate the polymerization reaction of the photo-radical polymerizable monomer.

As the photo-radical polymerization initiator, it is possible to employ, for example, imidazole derivatives, organic azide compounds, titanocene, organic peroxides, and thioxanthone derivatives. Specific examples of the photo-radical polymerization initiator include benzyl, benzoin, benzoin ethyl ether, benzoin isopropyl ether, benzoin butyl ether, benzoin isobutyl ether, 1-hydroxycyclohexyl phenyl ketone, benzyl methyl ketal, benzyl ethyl ketal, benzyl methoxyethyl ether, 2,2′-diethylacetophenone, 2,2′-dipropylacetophenone, 2-hydroxy-2-methylpropiophenone, p-tert-butyltrichloroacetophenone, thioxanthone, 2-chlorothioxanthone, 3,3′,4,4′-tetra(t-butyl peroxycarbonyl)benzophenone, 2,4,6-tris(trichloromethyl)1,3,5-triazine, 2-(p-methoxyphenyl)-4,6-bis(trichloromethyl)1,3,5-triazine, 2-[(p-methoxyphenyl)ethylene]-4,6-bis(trichloromethyl)1,3,5-triazine, di-t-butyl peroxide, dicumyl peroxide, t-butylcumyl peroxide, t-butyl peroxyacetate, t-butyl peroxyphthalate, t-butyl peroxybenzoate, acetyl peroxide, isobutyryl peroxide, decanoyl peroxide, lauroyl peroxide, benzoyl peroxide, t-butyl hydroperoxide, cumene hydroperoxide, methylethyl ketone peroxide, cyclohexanone peroxide, etc.

The above-mentioned photo-radical polymerization initiators are preferably added to the raw material solution with a content ranging from 0.1 to 10 wt % on the radical polymerizable monomer. If the content of these photo-radical polymerization initiators is less than 0.1 wt %, it may become impossible to obtain a sufficient change in refractive index. On the other hand, if the content of these photo-radical polymerization initiators exceeds 10 wt %, light absorption by the recording layer would become too large, thereby possibly deteriorating the resolution. More preferably, the content of the photo-radical polymerization initiator is confined to 0.5 wt % to 6 wt % on the radical polymerizable monomer.

If necessary, a sensitizing dye such as cyanine, merocyanine, xanthene, coumalin, eosin, etc., a silane coupling agent and a plasticizer can be added to the raw material solution for the recording layer.

The holographic recording medium and a holographic recording system employing a holographic recording material according to an embodiment of the present invention are explained.

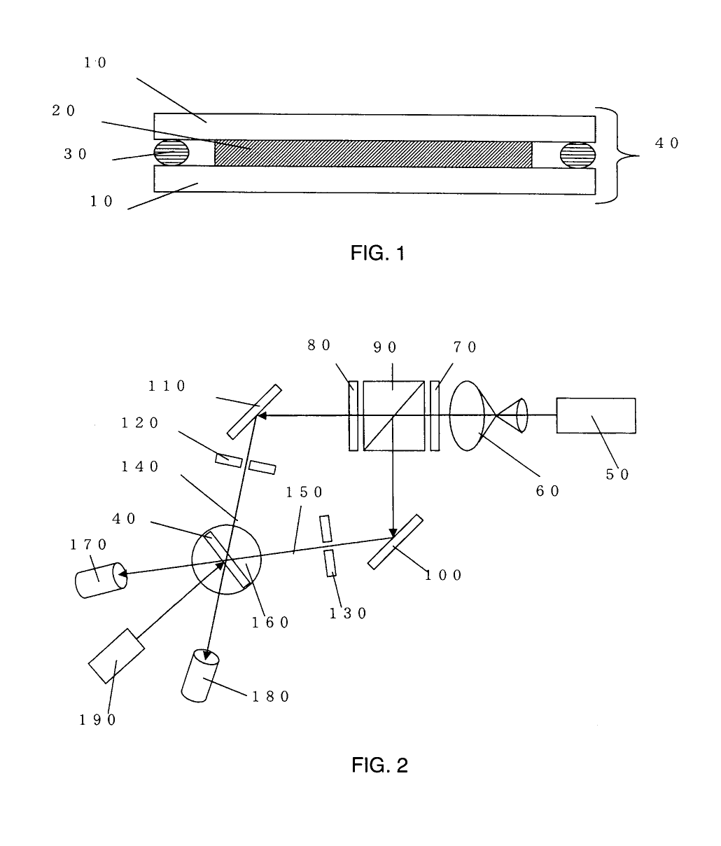

FIG. 1 is a sectional view of the holographic recording medium using the holographic recording material according to the embodiment of the invention. Wherever possible, the same reference numerals will be used to denote the same or like portions throughout figures, and overlapped explanations are omitted below.

A holographic recording medium 40 includes a spacer 30 to hold a recording layer 20 sandwiched by two upper and lower transparent substrates 10, and a recording layer 20.

It is preferable that the transparent substrates 10 are optically transparent. Materials of the transparent substrates 10 include glass, polycarbonate, etc.

The recording layer 20 includes the radical polymerizable monomer and the photo-radical polymerization initiator in addition to the epoxy monomer and the catalyst.

The spacer 30 is formed of, e.g., a circular resin, and is sandwiched by the two upper and lower transparent substrates 10, thereby serving to prevent the liquid recording layer 20 from flowing out of the two substrates 10 when curing the liquid recording layer 20.

The manufacturing method of the holographic recording medium 40 is described below. A radical polymerizable monomer and a photo-radical polymerization initiator are added to an epoxy monomer and a catalytic component to prepare the raw material solution for the recording layer 20. This resinic raw material solution is poured into a space formed between a pair of transparent glass substrates 10 with a spacer being interposed therebetween. The resin layer thus formed is then heated using an oven, a hot plate, etc., to allow the radical polymerization of epoxy monomer to proceed, thereby forming the recording layer 20 with the three-dimensional cross-linking polymer matrix. The temperature in this heating step is preferably within the range of 10° C. to 80° C., and is more preferably from 10° C. to 60° C. Since this reaction can take place sufficiently even at room temperature, it is preferable to employ a method to cure the resin layer at room temperature.

As the film thickness of the recording layer, the thickness is preferably within a range of 0.1 mm to 5 mm, and is more preferably from 0.2 mm to 2 mm. If the film thickness of the recording layer exceeds 5 mm, a light transmission may be possibly reduced. Therefore, the thickness is confined to not more than 5 mm.

FIG. 2 is a view of a recording/reproducing system employing the holographic recording medium 40 according to the embodiment of the invention.

As shown in FIG. 2, the holographic recording/reproducing system includes the followings:

the holographic recording medium 40;
a light source 50;
a beam expander 60;
optical elements 70 and 80 for optical rotation;
a polarized beam splitter 90;
mirrors 100 and 110;
electromagnetic shutters 120 and 130;
a reference beam 140 emitted from the light source 50;
an information beam 150;
a rotary stage 160;
optical power detectors 170 and 180; and
an ultraviolet source 190.

The reference beam 140 reflected by the mirror 110 and the information beam 150 reflected by the mirror 100 make interference with each other to form a hologram in the holographic recording medium, thereby allowing it to record information.

As the light source 50, various light sources which emit various beams to be coherent in the recording layer 20 of the holographic recording medium 40 can be employed. However, a linear polarization laser is preferably employed from the view point of coherency. The lasers include, e.g., a semiconductor laser, a He—Ne laser, an Ar laser, a YAG laser, etc.

The beam expander 60 expands the diameter of the beam emitted from the light source 50 to a beam diameter suitable for the holographic recording.

The optical elements 70 and 80 for optical rotation are arranged so as to sandwich the polarized beam splitter 90, and generate a beam including S-polarized beam and P-polarized beam components. A half- or quarter-wavelength plate is employed, for example.

Optical paths through the polarized beam splitter 90, the mirrors 100, 110, and the electromagnetic shutters 120, 130 are used to divide the information beam 150 from the reference beam 140 both coming out of the holographic recording medium 40 at the time of reproducing the holograms recorded on the holographic recording medium 40. The recording layer of the holographic recording medium 40 is irradiated with the reference beam 140 and the information beam 150 to record information thereon.

The information beam 150 is produced by a spatial beam modulator (not shown) provided to the mirror 100. The spatial beam modulator modulates the intensity of the beam emitted from the light source 50 into a grid binary pattern with bright and dark points. It is preferable to employ DMD (digital micromirror device), ferroelectric liquid crystal, etc. for the spatial beam modulator.

The optical power detectors 170 and 180 are used in order to detect signal light for reproducing a hologram recorded on the recording layer 20 of the holographic recording medium 40.

The ultraviolet source 190 is used in order to stabilize a hologram formed in the recording layer 20 of the holographic recording medium 40. Here, “to stabilize” means to polymerize unreacted radical polymerizable monomers in the recording layer of the holographic recording medium. Examples for the ultraviolet source 190 include, e.g., a xenon lamp, a mercury lamp, a high-pressure mercury lamp, a mercury xenon lamp, a GaN-series light-emitting diode, a GaN-series semiconductor laser, an eximer laser, a third harmonic (355 nm) of a Nd:YAG laser, a fourth harmonic (266 nm) of a Nd:YAG laser.

A method for recording onto the holographic recording medium 40 is explained below.

The beam emitted from the light source 50 is introduced into the polarized beam splitter 90 through the beam expander 60 and the optical element 70 for optical rotation. The information beam 150 is produced by the spatial beam modulator (not shown) provided to the mirror 100. The spatial beam modulator modulates the intensity of the S-polarized beam component reflected by the polarized beam splitter 90. The S-polarized beam component is included in the beam which has passed through the optical element 70 for optical rotation. The P-polarization beam component passes through the polarized beam splitter 90 and the mirror 110 to serve as the reference beam 140. The direction of optical rotation of the beam to be incident on the beam splitter 90 is controlled using the optical element 70 for optical rotation so that the intensities of the information beam 150 and the reference beam 140 are equal to each other at a position of the recording layer 20 of the holographic recording medium 40.

The information beam 150 reflected by the mirror 100 passes through the electromagnetic shutter 130, and is directed to the recording layer 20 of the holographic recording medium 40 held on the rotary stage 160.

On the other hand, the optical element 80 for optical rotation rotates by 90° the polarization direction of the reference beam 140 that has passed through the polarized beam splitter 90, thereby creating an S-polarized beam. This S-polarized beam is then reflected by the mirror 110 and allowed to pass through the electromagnetic shutter 120. Thereafter, the S-polarized beam is directed so as to intersect with the information beam 150 within the recording layer 20 of the holographic recording medium 40 which is held on the rotary stage 160, thereby creating a hologram to record information.

A method for reproducing the information recorded on the holographic recording medium 40 is explained below.

For reproducing the holograms formed in the holographic recording medium, the electromagnetic shutter 130 is closed to shut off the information beam 150. Then, only the reference beam 140 is directed to the holograms which have been formed in the recording layer 20 of the holographic recording medium 40. A portion of the reference beam 140 is diffracted by the holograms when the portion passes through the holographic recording medium 40. The resultant diffracted beam, i.e., a signal beam, is then detected by a beam detector 170. At this time, the optical power detector 180 monitors the beam which passes through the holographic recording medium 40.

Alternatively, in order to stabilize the holograms which have been recorded, unreacted radical polymerizable monomer may be irradiated with ultraviolet using the ultraviolet source 190 to react the unreacted monomer. It is possible to promote the polymerization reaction of the unreacted monomer by applying heat with a heater (not shown) provided to the rotary stage 160 even without the ultraviolet source 190.

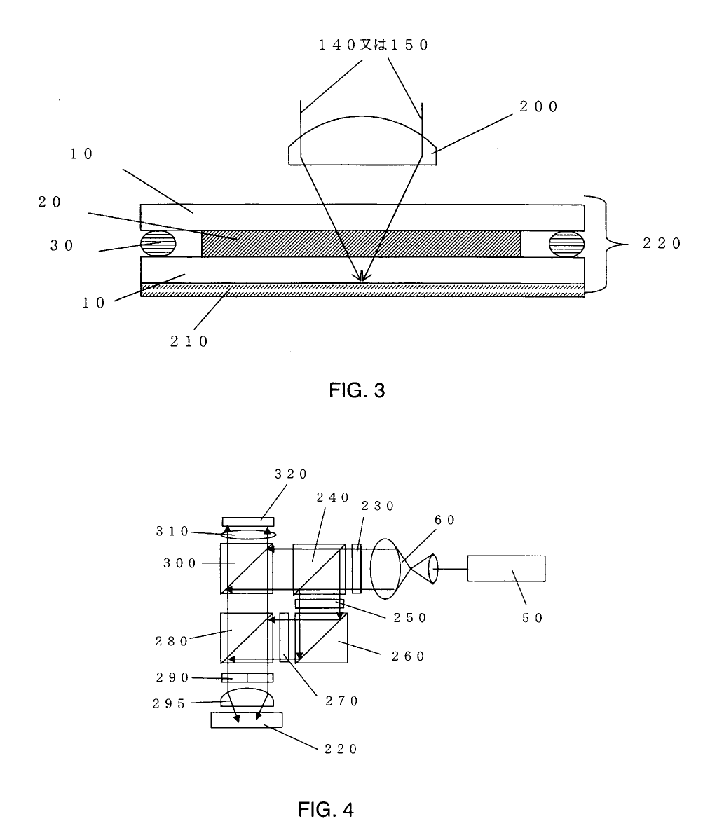

FIG. 3 is a view showing a reflection type holographic recording medium 220 using the holographic recording material according to the embodiment of the invention. The reflection type holographic recording medium 220 includes the transparent substrate 10, the recording layer 20, the spacer 30, and a reflecting layer 210. The reference beam 140, the information beam 150, an object lens 200 are shown with the reflection type holographic recording medium 220. The reference beam 140 and the information beam 150 are emitted from the light source (not shown). The object lens 200 serves to focus the reference beam 140 and the information beam 150. The reflecting layer 210 is formed when the holographic recording medium 220 is configured for a reflection type. The reflecting layer 210 is formed of a material, e.g., aluminum, etc. with high reflectance for a recording light wavelength.

It is greatly different from the above-mentioned holographic recording medium 40 in FIG. 1 to provide the reflecting layer 210 to a holographic recording medium. The reflecting layer 210 is formed when the holographic recording medium 220 is configured for a reflection type. That is, it is a technique of providing an optical power detector etc. to the side on which light for recording/reproducing is emitted to detect the light reflected on the reflecting layer 210. With the reflection type holographic recording medium 220, the whole optical system can be made simple.

FIG. 4 is a schematic view showing a holographic recording/reproducing system using the reflection type holographic recording medium 220. The holographic recording/reproducing system shown in FIG. 4 is provided with the followings:

the light source 50;
the beam expander 60;
an optical element 230 for optical rotation;
polarized beam splitters 240, 260, and 280;
a beam splitter 300;
an imaging lens 310;
a spatial light modulator 250;
an electromagnetic shutter 270;
a halving optical element 290 for optical rotation;
a two-dimensional optical power detector 320;
an object lens 295; and
the reflection type holographic recording medium 220.

The reflection type holographic recording medium 220 is disposed so that the medium 220 faces the object lens 295.

The two-dimensional optical power detector 320 is used in order to detect a reflected beam at the time of reproducing from the reflection type holographic recording medium 220. Image sensors, such as a CCD and a CMOS element, can be employed for the two-dimensional optical power detector 320.

The right-hand side portion and the left-hand side portion of the halving optical element 290 for optical rotation differs in an optical characteristic from each other in FIG. 4. The halving optical element 290 for optical rotation is described in detail in a principle of the operation thereof.

A method for recording onto the reflection type holographic recording medium 220 is explained below.

The beam expander 60 expands the beam diameter of a beam emitted from the light source 50 to make a parallel pencil. The parallel pencil is incident onto the optical element 230 for optical rotation. The optical element 230 for optical rotation serves to divide light into the S-polarized beam component and the P-polarized beam component. The S-polarized beam component is reflected by the polarized beam splitter 240, and is allowed to enter the spatial light modulator 250 to generate the information beam. Then, the information beam is incident onto the polarized beam splitter 260. This polarized beam splitter 260 acts to reflect only the S-polarized beam component out of the previous information beam while allowing the P-polarized beam component to pass therethrough.

The S-polarized beam component that has been reflected by the polarized beam splitter 260 is allowed to pass through the electromagnetic shutter 270 and to be incident onto another polarized beam splitter 280. This information beam is then reflected by the polarized beam splitter 280, and allowed to be incident onto the halving optical element 290 for optical rotation.

Among the information beams having entered the halving optical element 290 for optical rotation, the beam component to be incident on the right side portion of this halving optical element 290 for optical rotation is allowed to emit therefrom after the plane of polarization thereof is rotated by an angle of +45°, while the beam component to be incident on the left side portion of this halving optical element 290 is allowed to emit therefrom after the plane of polarization thereof is rotated by an angle of −45°. The beam component to be derived from the S-polarized beam component whose polarization plane has been rotated by an angle of +45° (or the beam component to be derived from the P-polarized beam component whose polarization plane has been rotated by an angle of −45° will be hereinafter referred to as an A-polarized beam component. The beam component to be derived from the S-polarized beam component whose polarization plane has been rotated by an angle of −45° (or the beam component to be derived from the P-polarized beam component whose polarization plane has been rotated by an angle of +45°) will be hereinafter referred to as a B-polarized beam component.

The A-polarized beam component and the B-polarized beam component that have been emitted from the halving optical element 290 for optical rotation are converged on the reflection type holographic recording medium 220 by an object lens 295.

On the other hand, the P-polarized beam component from the optical element 230 for optical rotation is allowed to pass through the polarized beam splitter 240. This P-polarized beam component is used as a reference beam. The reference beam is reflected by the beam splitter 300, and is allowed to pass through the polarized beam splitter 280. This reference beam that has passed through the polarized beam splitter 280 is then incident on the halving optical element 290 for optical rotation. The beam component to be incident on the right side portion of this halving optical element 290 is allowed to be emitted therefrom as a B-polarized beam component after the plane of polarization thereof is rotated by an angle of +45° while the beam component to be incident on the left side portion of this halving optical element 290 is allowed to be emitted therefrom as an A-polarized beam component after the plane of polarization thereof is rotated by an angle of −45°. Subsequently, these A-polarized beam component and B-polarized beam component are converged on the reflection type holographic recording medium 220 by the object lens 295.

As mentioned above, the information beam formed of the A-polarized beam component and the reference beam formed of the B-polarized beam component are emitted from the right side portion of the halving optical element 290. On the other hand, the information beam formed of the B-polarized beam component and the reference beam formed of the A-polarized beam component are emitted from the left side portion of the halving optical element 290 for optical rotation. Furthermore, these information beam and reference beam are converged on the reflection type holographic recording medium 220.

Therefore, an interference between the information beam and the reference beam takes place only between the information beam formed of the direct beam that has been directly incident on the recording layer 20 through the transparent substrate 10 constituting the reflection type holographic recording medium and the reference beam formed of the reflection beam that has been reflected by the reflection layer 22, or only between the reference beam formed of a direct beam and the information beam formed of a reflection beam. Furthermore, neither the interference between the information beam formed of a direct beam and the information beam formed of a reflection beam nor the interference between the reference beam formed of a direct beam and the reference beam formed of a reflection beam can take place. Therefore, according to the recording/reproducing system shown in FIG. 4, it is possible to produce a distribution of optical properties in the recording layer 20 in conformity with the information beam.

Alternatively, also in the reflection-type holographic recording/reproducing system shown in FIG. 4, it is possible to provide the system with the ultraviolet source 190 mentioned above in order to enhance the stability of recorded holograms.

A method for reproducing the information recorded on the reflection type holographic recording medium 220 is explained below.

The electromagnetic shutter 270 is closed to allow only the reference beam to pass through, thus irradiating the reflection type holographic recording medium 220 having information recorded in advance therein with only the reference beam. As a result, only the reference beam formed of the P-polarized beam component is allowed to reach the halving optical element 290 for optical rotation.

Owing to the effects of the halving optical element 290 for optical rotation, this reference beam is processed such that the beam component incident on the right side portion of this halving optical element 290 for optical rotation is emitted therefrom as a B-polarized beam component after the plane of polarization thereof is rotated by an angle of +45°, while the beam component incident on the left side portion of this halving optical element 290 for optical rotation is emitted therefrom as an A-polarized beam component after the plane of polarization thereof is rotated by an angle of −45°. Subsequently, these A-polarized beam component and B-polarized beam component are converged on the holographic recording medium 220 by the object lens 34.

In the recording layer 20 of the holographic recording medium 220, there is formed, according to the above-mentioned method, a distribution of optical properties created in conformity with the information to be recorded. Accordingly, a portion of these A-polarized beam component and B-polarized beam component that have been incident on the reflection type holographic recording medium 220 is diffracted by the distribution of optical properties created in the recording layer 20 and is then emitted as a reproducing beam out of the reflection type holographic recording medium 220.

In the reproducing beam emitted from the reflection type holographic recording medium 220, the information beam is reproduced therein, so that the reproducing beam is formed into a parallel beam by the object lens 295 and then allowed to reach the halving optical element 290 for optical rotation. The B-polarized beam component having been incident on the right side portion of the halving optical element 290 for optical rotation is emitted therefrom as the P-polarized beam component. In addition, the A-polarized beam component having been incident on the left side portion of the halving optical element 290 for optical rotation is emitted therefrom also as the P-polarized beam component. In this manner, it is possible to obtain a reproducing beam as the P-polarized beam component.

Then, the reproducing beam passes through the polarized beam splitter 280. A portion of the reproducing beam that has passed through the polarized beam splitter 280 is then allowed to pass through the beam splitter 300, and further passes through an image-forming lens 310 onto the two-dimensional beam detector 320, thereby reproducing an image of the spatial beam modulator 250 on the two-dimensional beam detector 320. In this manner, it is possible to reproduce the information recorded onto the reflection type holographic recording medium 220.

On the other hand, the rests of the A-polarized beam component and of the B-polarized beam component that have passed through the halving optical element 290 for optical rotation into the reflection type holographic recording medium 220 are reflected by the reflecting layer 210, and emitted from the reflection type holographic recording medium 21. These A-polarized beam component and B-polarized beam component that have been reflected as a reflection beam are then turned into a parallel pencil by the object lens 295. Subsequently, the A-polarized beam component of this parallel pencil is incident on the right side portion of the halving optical element 290 for optical rotation, and then emitted therefrom as the S-polarized beam component, while the B-polarized beam component of this parallel beam is incident on the left side portion of the halving optical element 290 for optical rotation, and then emitted therefrom as the S-polarized beam component. Since the S-polarized beam component thus emitted from the halving optical element 290 for optical rotation is reflected by the polarized beam splitter 280, the S-polarized beam component is not allowed to reach the two-dimensional beam detector 320. Therefore, according to this recording/reproducing system, it is now possible to yield an excellent reproducing signal-to-noise ratio.

The present invention is not limited to the above-described embodiments. When those skilled in the art appropriately change or modify the designs of the holographic recording medium and the recording/reproducing system, the holographic recording medium and the recording/reproducing system to practice all the changed or modified ones, and the same effect as described above can be obtained, they are also incorporated in the present invention.

A method for synthesizing a radical polymerizable monomer employed in this embodiment is explained specifically.

A sulphur-containing compound expressed with the above-mentioned general formula (1) is synthesized according to a Grignard reaction (the following method A) using a bromo compound, a Wittig reaction (the following method B and method C) using an aldehyde compound or a bromomethyl compound, etc.

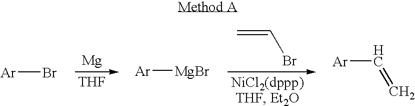

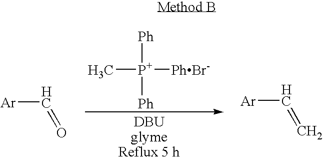

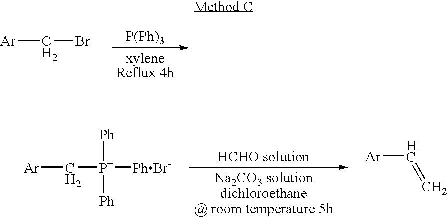

Synthesis examples using the above-mentioned synthesizing methods are mentioned below.

### Synthesis Example 1

### Synthesis of 2-vinyl dibenzothiophene

2-vinyl dibenzothiophene was synthesized using the above mentioned method A under the following conditions.

Under a nitrogen atmosphere, 154.0 g (836 mmol) of dibenzothiophene was taken into a 2 L-flask provided with a stirrer and a dropping funnel, and 850 mL of chloroform was added to the flask to be dissolved. The resultant solution was cooled at 0° C. by a NaCl-ice bus, and 136.1 g (852 mmol) of bromine was dropped over 40 minutes. In the meantime, the temperature of the resultant solution was held at 0° C. After stirring at 0° C. for 30 minutes, the resultant solution was warmed to room temperature to be stirred for 3 days.

The reaction solution was filtered, and the crystal precipitated was washed to be filtered twice by 200 mL of methanol. Vacuum drying of the obtained crystal was carried out at 50° C. for 3 hours, and 2-bromo dibenzothiophene was obtained. The obtained was a white powder crystal. The yield of the white powder crystal was 64.6 g (245 mmol, a yield ratio of 29%).

9.83 g (404 mmol) of magnesium was taken into a 2 L-flask provided with a stirrer, a dropping funnel and a condenser tube, and nitrogen was flowed to the flask while heating at 100° C. After cooling the flask, 105.3 g (400 mmol) of 2-bromo dibenzothiophene was dropped by a small amount to be dissolved in 350 mL of dried THF (tetrahydrofuran). A small amount of iodine was added to the flask to start a reaction in the flask by heating. The THF solution of 2-bromo dibenzothiophene was dropped over 1 hour. In the meantime, the temperature of the flask was kept at 45° C. to 50° C. while sometimes cooling the flask with water. 50 mL, 70 mL, and 100 mL of dried THF were added just after the starting of the reaction, on the way of the dropping, and at the last time of the dropping, respectively. The resultant solution was stirred at 50° C. for 1 hour after finishing the dropping while heating with warm water.

The flask having the resultant solution was cooled down to 4° C. with ice, and 272 mg (0.502 mmol) of NiCl₂ (dppp) was slurried to add to 350 mL of drying diethylether. Subsequently, 410 mL (410 mmol) of 1-molar THF solution of vinyl bromide was dropped to the flask over 40 minutes. The temperature of the flask was held at 4° C. to 6° C. during the dropping. After the dropping followed by stirring at 4° C. to 6° C. for 20 minutes, the resultant solution in the flask was warmed to room temperature. The resultant solution was further stirred at room temperature for 23 hours.

300 mL of chloride (0.95N) was dropped while cooling the flask with ice. In the meanwhile, the temperature of the solution went up to 20° C. 1.2 L of diethylether was added to the reaction mixture after dropping 300 mL of chloride (0.95N) to be extracted. An organic layer was separated from the reaction mixture with 1.2 L of diethylether added, and washed three times with 300 mL of water. The organic layer was further washed to be separated with 300 mL of saturated saline. After drying the separated organic layer with sodium sulfate followed by filtering, vacuum concentration of the filtrate was carried out.

Silica gel 336 g was mixed to the concentrated liquid so that the solvent was distilled away completely to adsorb the reaction mixture to the silica gel. Column chromatography was carried out using 3.2 kg of silica gel and hexane as eluate in order to refine this. Thereby, 2-vinyl dibenzothiophene of high purity was obtained. The yield of 2-vinyl dibenzothiophene obtained was 35.0 g (166 mmol). The GC purity and the yield ratio of 2-vinyl dibenzothiophene obtained were 42% and 99.3%, respectively.

The chemical formula of 2-vinyl dibenzothiophene (2VDbt) is C₁₄H₁₀S (Mw=210.298 g/mol), and the melting point thereof is 42° C. to 43° C.

An H-NMR measurement of the 2-vinyl benzothiophene obtained was conducted. The H-NMR measurement showed the following chemical shifts

H-NMR (δ):

5.32 ppm (1H);

5.86 ppm (1H);

6.89 ppm (1H);

7.44-7.47 ppm (2H);

7.77-7.83 ppm (2H);

7.54 ppm (1H); and

8.13-8.17 ppm (2H),

thereby allowing it to identify 2-vinyl dibenzothiophene.

Furthermore, an ultimate analysis was conducted. The analysis showed C: 79.83%, H: 4.81%, and S: 15.33%. The analysis also coincided well with a calculation C: 79.96%, H: 4.79%, S: 15.25%, thereby allowing it to identify 2-vinyl dibenzothiophene.

### Synthesis Method 2

### Synthesis of 2-vinyl benzothiophene

2-vinyl benzothiophene was synthesized using the synthesizing method B.

21.44 g (60 mmol) of methyltriphenyl phosphonium bromide was taken into a 200 mL-flask with a stirrer and a condenser tube, and 80 mL of glyme was added to the flask to be stirred while heating the flask at 50° C. in an oil bath. 10.05 g (66 mmol) of DBU was further added, and heated to reflux for 30 minutes. Furthermore, 5.00 g (30.8 mmol) of benzothiophene-2-carboaldehyde was added, and heated to reflux for 4 hours.

After cooling, the reacted liquid was filtered to remove insoluble matters. Then, the filtrate with 200 mL of isopropyl-ether added was separated and washed twice with 200 mL of water. After the organic layer separated from the filtrate was dried with sodium sulfate to be further filtered, vacuum concentration of the filtrate of the organic layer was carried out.

The concentrate was refined with silica gel column chromatography (elution liquid: cyclohexane), and 2-vinyl benzothiophene of high purity was obtained. The yield was 4.72 g (29.5 mmol). The GC purity and the yield ratio were 96% and 99.0%, respectively.

The chemical formula of 2-vinyl benzothiophene (2VBt) is C₁₀H₈S (Mw=160.238 g/(mol)), and the melting point thereof is 65° C. to 66° C.

An H-NMR measurement of the 2-vinyl benzothiophene obtained was conducted. The H-NMR measurement showed the following chemical shifts

H-NMR (δ):

5.30 ppm (1H);

5.66 ppm (1H);

6.87-6.97 ppm (1H);

7.17 ppm (1H);

7.26-7.34 ppm (2H); and

7.65-7.78 ppm (2H),

thereby allowing it to identify 2-vinyl dibenzothiophene.

Furthermore, an ultimate analysis was carried out. The analysis showed C: 75.19%, H: 4.99%, and S: 19.82%. The analysis also coincided well with a calculation C: 74.96%, H: 5.03%, S: 20.01%, thereby allowing it to identify 2-vinyl benzothiophene.

### Synthesis Example 3

### Synthesis of 4-vinyl dibenzothiophene

4-vinyl dibenzothiophene was synthesized using the above mentioned method C.

11.1 g (40 mmol) of 4-bromomethyl dibenzothiophene and 10.5 g (40 mmol) of triphenylphosphine were taken into a 500 mL-flask with a stirrer and a condenser tube, and 200 mL of xylene was added to the flask to be dissolved while heating the flask in an oil bath to be heated to reflux for 4 hours. After cooling, suction filtration was carried out to obtain a precipitated crystal. The precipitated crystal was washed with hexane, and dried in a vacuum, thus providing a raw crystal of (dibenzothiophene 4-yl)methyl triphenyl phosphonium bromide.

The raw crystal of (dibenzothiophene 4-yl)methyl triphenyl phosphonium bromide was taken into a 300 mL flask with a stirrer, and 100 mL of ethylene chloride was added to be dissolved while stirring. 30 mL (402 mmol) of 37% (about 13.4M) formaldehyde water solution is added to the above resultant solution to be stirred. Then, a saturated aqueous solution including 8.5 g (80 mmol) of sodium carbonate was further added to the above resultant solution to react the resultant solution while stirring for 5 hours.

100 mL of water was added to the reaction solution thus obtained to be stirred. Then an organic layer was separated from the reaction solution with a separating funnel to be washed with 100 mL of water. The organic layer was dried with sodium sulfate to be filtered. Then, vacuum concentration of the filtrate was carried out.

The concentrate was refined with silica gel column chromatography (elution liquid: cyclohexane), and 4-vinyl dibenzothiophene of high purity was obtained. The yield was 6.48 g (30.8 mmol). The GC purity and the yield ratio were 98.8% and 77%, respectively.

The chemical formula of 4-vinyl dibenzothiophene (4VDbt) is C₁₄H₁₀S (Mw=210.298 g/(mol)), and the melting point is 52° C. to 53° C.

An H-NMR measurement of the 4-vinyl dibenzothiophene obtained was conducted. The H-NMR measurement showed the following chemical shifts

H-NMR (δ):

5.30 ppm (1H);

5.84 ppm (1H);

6.86 ppm (1H);

7.44-7.55 ppm (4H);

7.83 ppm (1H); and

8.13-8.17 ppm (2H),

thereby allowing it to identify 4-vinyl dibenzothiophene.

Furthermore, an ultimate analysis was carried out. The analysis showed C: 79.83%, H: 4.81%, and S: 15.33%. The analysis also coincided well with a calculation C: 79.96%, H: 4.79%, S: 15.25%, thereby allowing it to identify 4-vinyl dibenzothiophene.

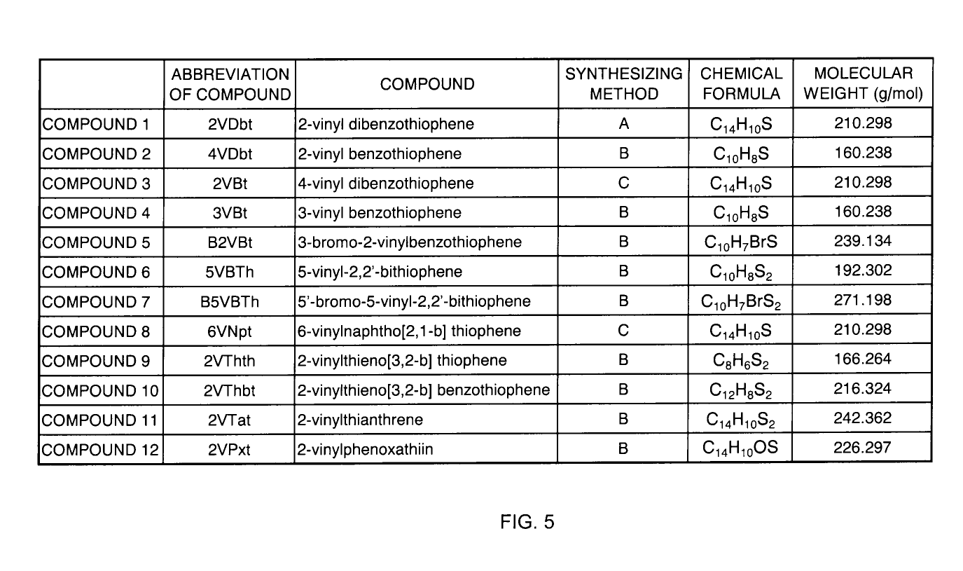

FIG. 5 is a table listing synthesized compounds and the synthesizing methods thereof. The compounds synthesized in the synthesis examples 1 to 3 correspond to the compounds 1 to 3 at the table, respectively.

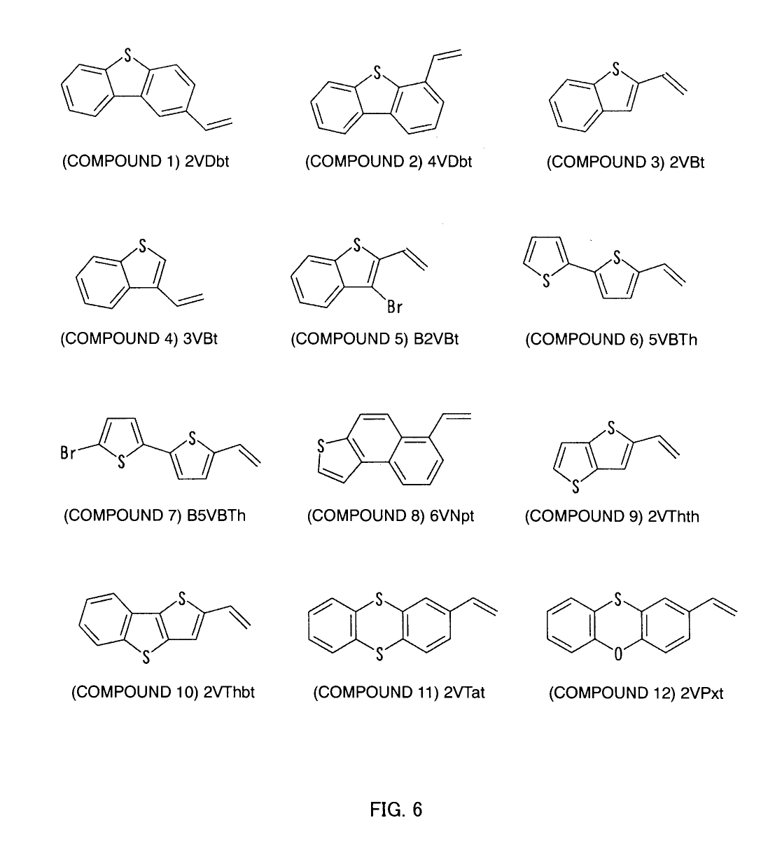

FIG. 6 shows chemical structural formulas of the compounds listed in the table of FIG. 5.

The holographic recording medium was produced and evaluated using the radical polymerizable monomer according to the present embodiment. The present invention will be explained below with reference to a method for evaluating the holographic recording medium, examples, and comparative examples.

The holographic recording medium was evaluated using a plane-wave measuring device generally used for the evaluation thereof. The test piece thus obtained was mounted on the rotary stage 160 of the holographic recording system shown in FIG. 2 to record a hologram. A semiconductor laser (405 nm) was employed as the light source 50. The beam spot size on the test piece was 5 mm in diameter for both the information beam 150 and the reference beam 140. The intensity of the recording beam was adjusted such that the intensity became 5 mW/cm² as a total of the information beam 150 and the reference beam 140.

After finishing the recording of a hologram, the information beam 150 was shut off by the electromagnetic shutter 130, and the test piece was irradiated with only the reference beam 140. Thereby, the diffracted beam was observed from the test piece. This confirmed that transmission type holograms were recorded therein. When the holographic recording medium was irradiated with the beam having an intensity of 500 mJ/cm², a maximum diffraction efficiency of 90% was obtained.

The recording performance of holograms was evaluated by an M/# (M number) representing a dynamic range of recording. The M/# can be defined by the following formula 1 using ηᵢ. This ηᵢ represents a diffraction efficiency to be derived from an i-th hologram when holograms of n pages are subjected to angular multiple recording/reproduction until the recording at the same region in the recording layer of the holographic recording medium becomes no longer possible. This angular multiple recording/reproduction can be performed by irradiating the holographic recording medium with a predetermined beam while rotating the medium.

$$M / \# = {\sum }_{i = 1}^{n} \sqrt{η i} \qquad ( 1 )$$

The diffraction efficiency η was defined by a light intensity Iₜ to be detected at the beam detector and a light intensity I_{d} to be detected at another beam detector on the occasion when the holographic recording medium was irradiated with only the reference beam. That is, the diffraction efficiency η was defined by an inner diffraction efficiency which can be expressed with η=I_{d}/(Iₜ+I_{d}).

As the M/# value of the holographic recording medium becomes larger, the dynamic range of recording can be further increased, thus allowing it to enhance a multiple recording performance. In this example, the thickness of the holographic recording medium 40 was set to be 200 μm to evaluate the M/#. Generally, it can be said that a good holographic recording medium has an M/# not less than 4.

Furthermore, in addition to the M/# value, it is necessary to calculate a volume change (volumetric shrinkage) in the holographic recording layer 20 before and after the holographic recording on the basis of the shift amount of the angle at which the diffraction efficiency from each hologram peaks.

In this example, the quantity of exposure per page of hologram was set to 1 mJ/cm², and the test piece was rotated by the rotary stage 13 once every time the recording of one page was finished. This recording was repeated to perform a holographic angular multiple recording of 30 pages. Furthermore, in order to wait for the accomplishment of reaction, the recording layer was left for 5 minutes without irradiating the recording layer with the beam. Thereafter, the diffraction efficiency η was measured while sweeping the rotary stage, thereby determining the M/# and the volumetric shrinkage. In addition, the test piece was cured at 80° C. for one month to be examined for the volumetric shrinkage thereof. This is for evaluating the holographic recording medium for the durability thereof.

When a radical polymerizable monomer polymerizes, the material obtained with polymerization generally shows a volumetric shrinkage. The volumetric shrinkage due to the polymerization at the time of optical recording brings about a negative influence on searching data from memorized holograms, and degrades performances of a waveguide element because of an increase in transmission loss, deviations of other performances, etc. Therefore, it is preferable that the volumetric shrinkage is as low as possible. For example, the volumetric shrinkage is preferably 0.5% or less, and is preferably reduced to 0.3% or less. If the volumetric shrinkage of the test piece after being cured at 80° C. for one month is 3% or less, a holographic recording medium made of the same recipe as that for the test piece is evaluated as a good one.

It is preferable to reduce the number of functional groups of the monomers to be polymerized for a necessary contrast of refractive index in order to keep down the volumetric shrinkage. Therefore, it is advantageous to induce a sufficiently large contrast of refractive index using a small number of monomers. Therefore, it is preferable that a contrast of the monomers is as large as possible.

It can be said that a good holographic recording medium has the M/# not less than 4 and the volumetric shrinkage not more than 0.3%.

The evaluation results of the holographic recording medium based on the above-mentioned valuation method, etc. are shown below with examples and comparative examples.

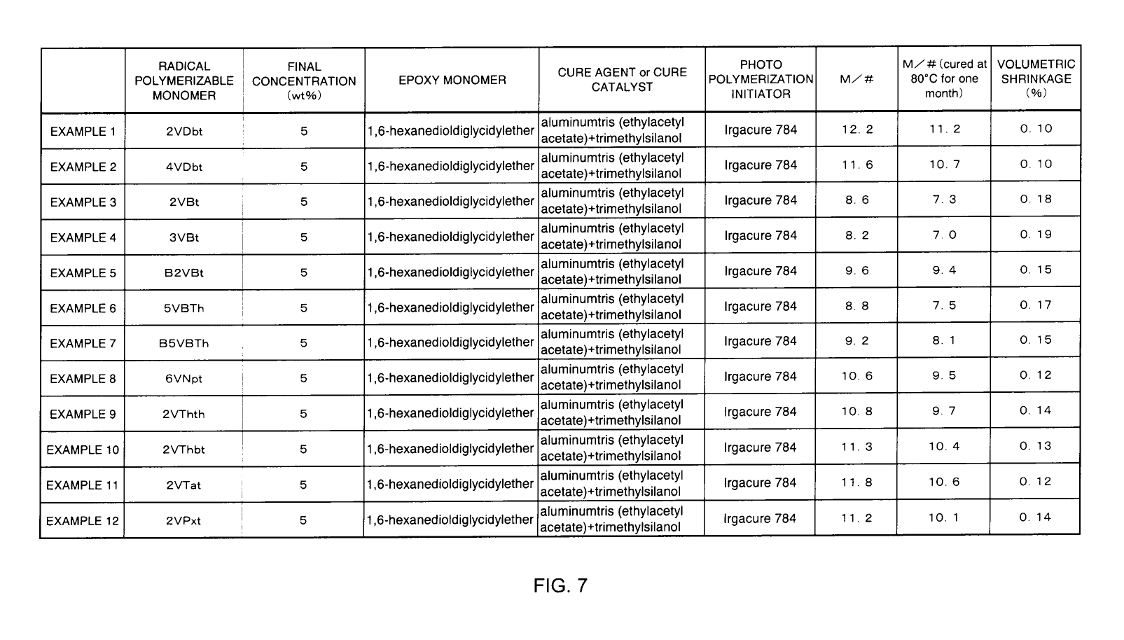

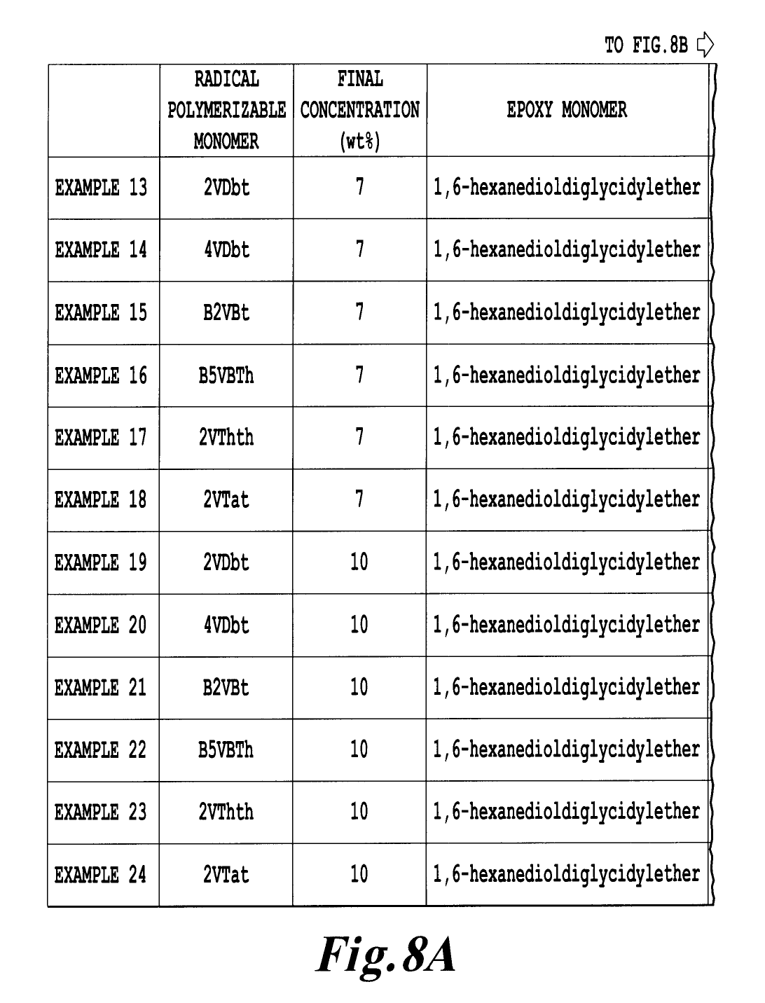

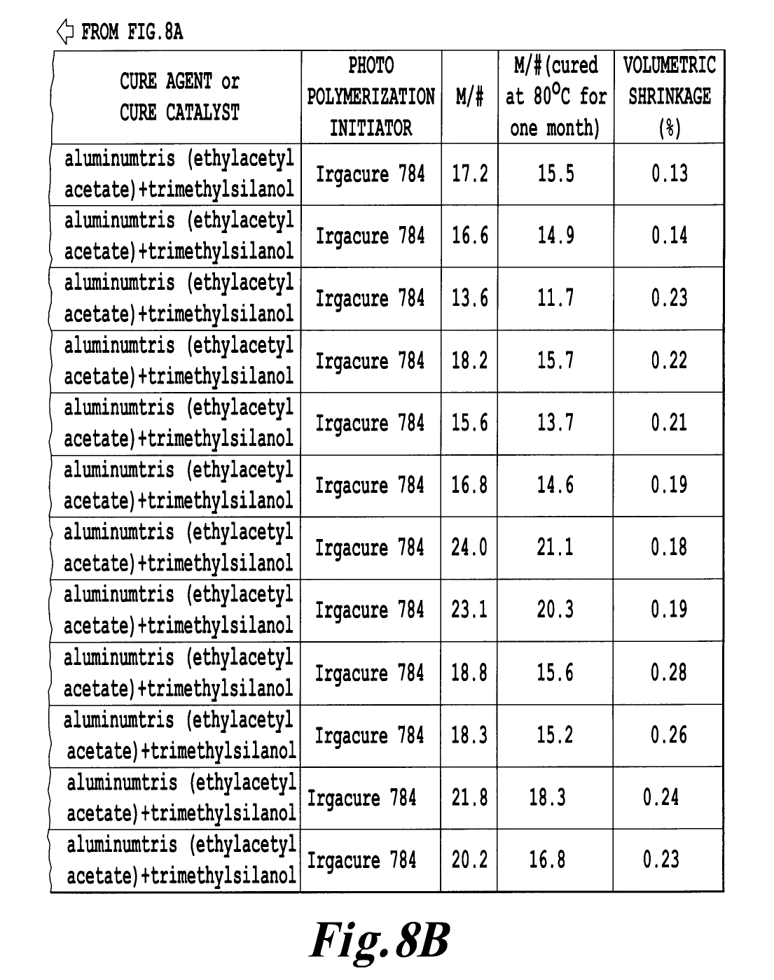

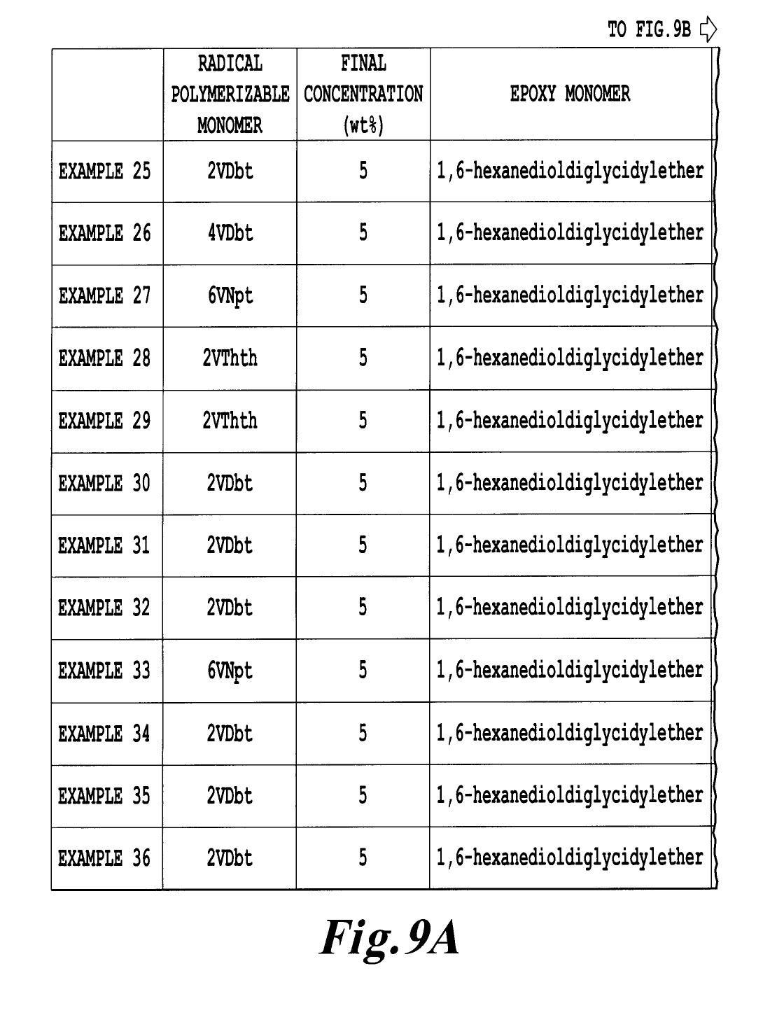

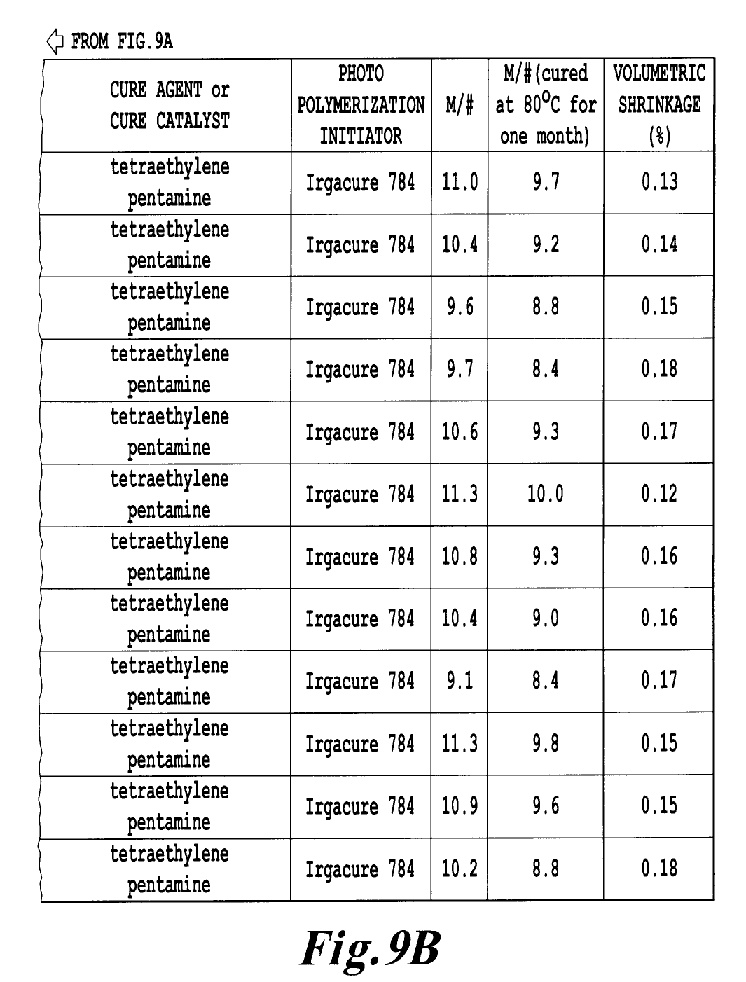

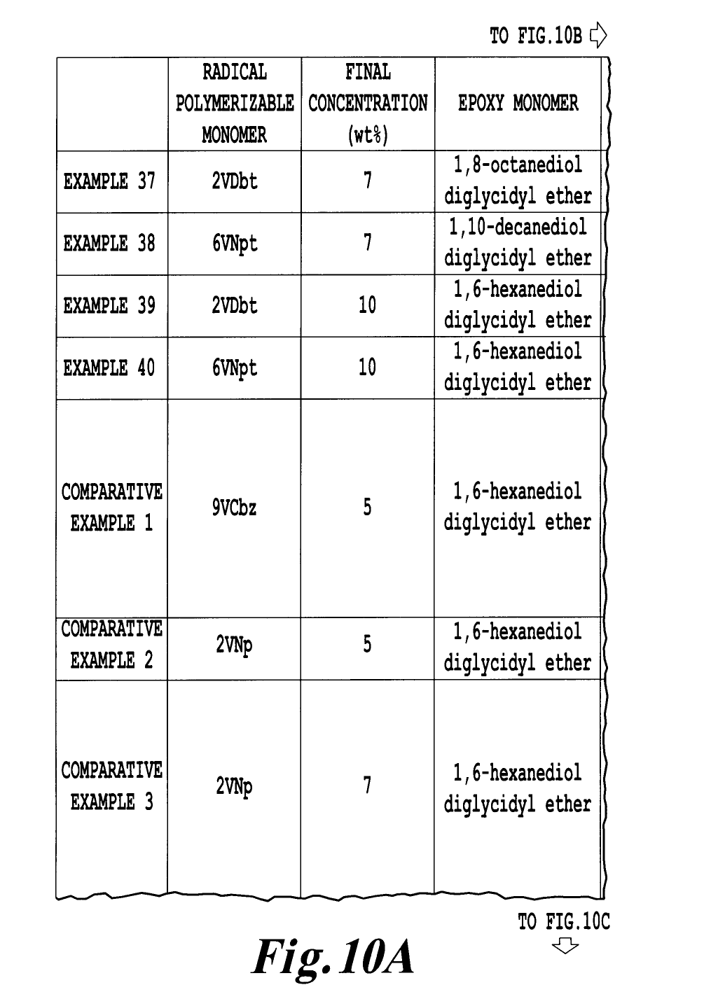

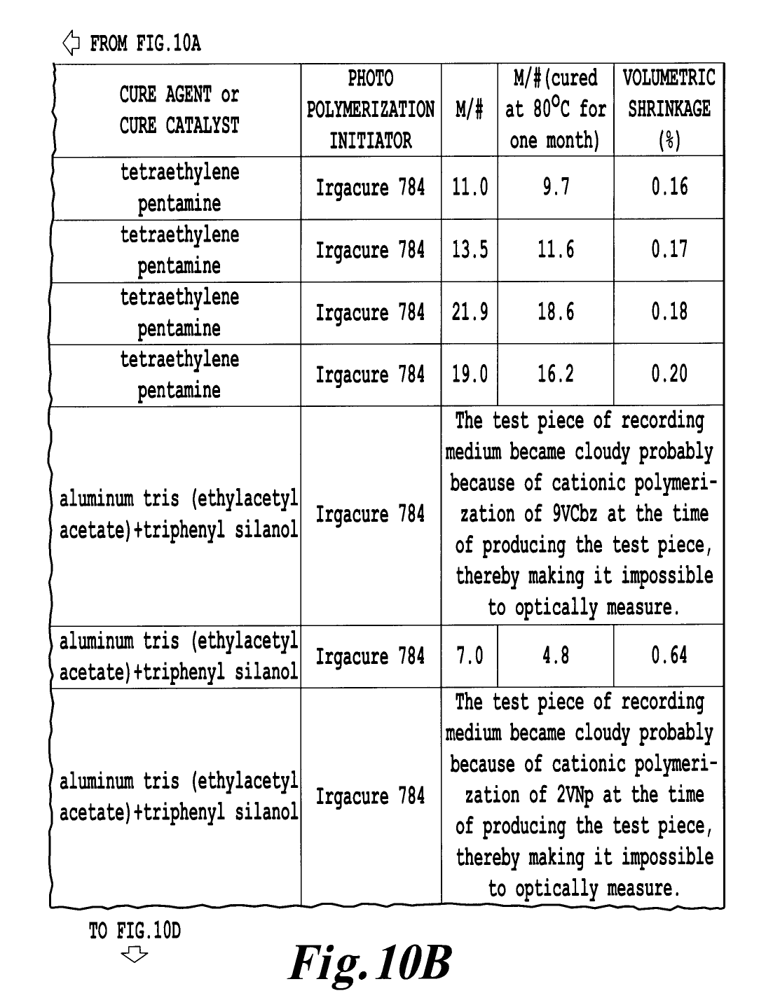

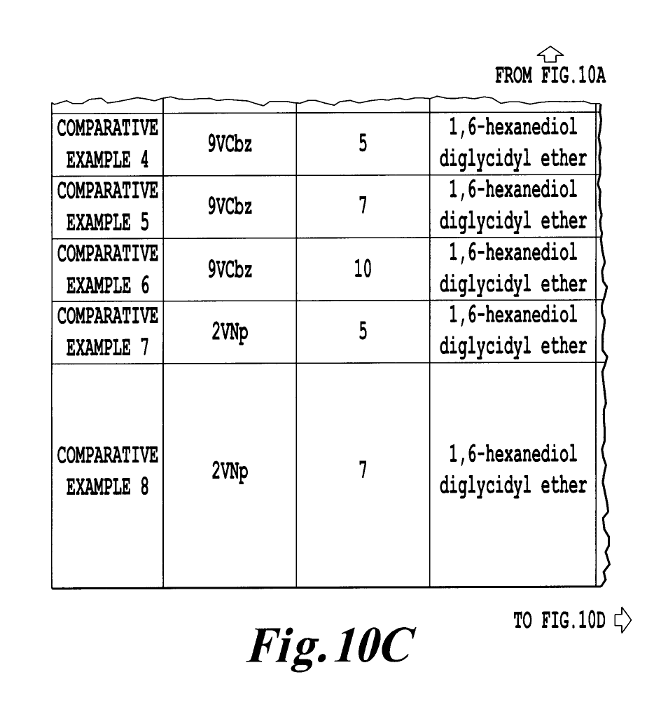

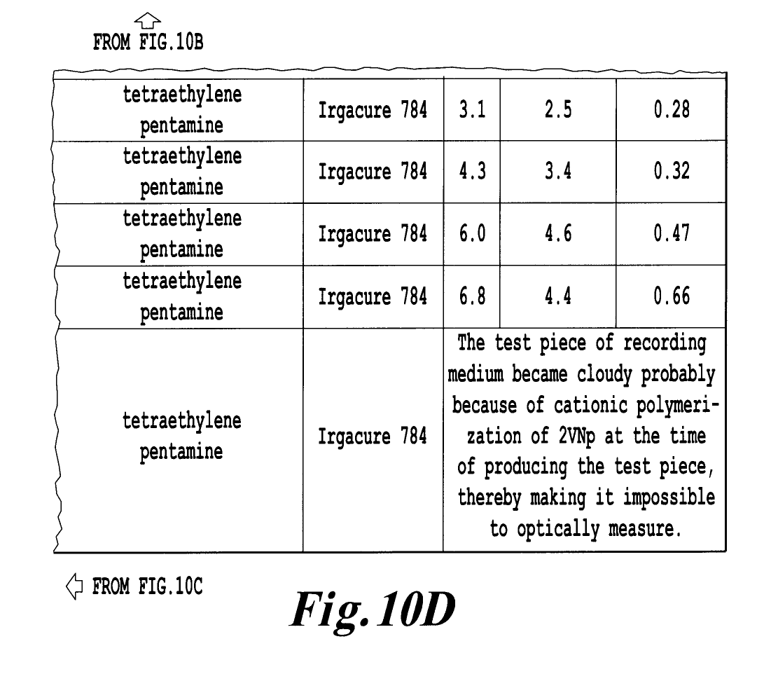

FIG. 7 is a table showing evaluation results for the examples 1 to 12 of the holographic recording medium according to the embodiment of the invention. FIG. 8 is a table showing evaluation results for the examples 13 to 24 of the holographic recording medium according to the embodiment of the invention. FIG. 9 is a table showing evaluation results for the examples 25 to 36 of the holographic recording medium according to the embodiment of the invention. FIG. 10 is a table showing evaluation results for the examples 37 to 40 of the holographic recording medium according to the embodiment of the invention. In addition, the evaluation result of the M/# of the holographic recording medium 40 right after being made is also shown for reference.

### Example 1

4.54 g of 1,6-hexanediol diglycidyl ether (epoxy equivalent: 151) employed as an epoxy monomer and 0.364 g of aluminum tris(ethylacetyl acetate) employed as a metal complex were mixed with each other in a dark room to obtain a mixture. This mixture obtained was then allowed to dissolve while stirring to prepare a solution of the metal complex.

Furthermore, 4.55 g of 1,6-hexanediol glycidyl ether (which has an epoxy equivalent weight 151) and 0.545 g of triphenyl silanol as alkyl silanol were mixed with each other to obtain a mixture.

A metal complex solution and the silanol solution were mixed with each other to further stir. 0.529 g of a radical polymerizable monomer and 0.042 g of a photo-radical polymerization initiator were added to the obtained solution. As the radical polymerizable monomer, 2VDbt of the compound 1 was employed. As the photo-radical polymerization initiator, bis(.eta.5-2,4-cylcopentadien-1-yl)-bis(2,6-difluoro-3-(1H-pyrrol-1-yl)-phenyl) titanium was employed. Finally, the solution was subjected to defoaming to obtain a raw material solution for the recording layer.

A spacer 30 made of a polytetrafluoroethylene sheet was disposed between a pair of glass plates to provide a space, and the above-mentioned raw material solution for the recording layer 20 was poured into the space. The resultant whole structure mentioned above was heated in a 55° C.-held oven for 6 hours under a light-shielded condition to obtain a test piece of the holographic recording medium 40 with a 200-μm thick recording layer.

As a result, the volumetric shrinkage of the test piece due to recording was 0.3% or less, and the M/# of the test piece after being cured at 80° C. for one month was 4 or more, thereby yielding a good holographic recording medium.

### Examples 2 to 24

The holographic recording media were produced for examples 2 to 24 as well as in the example 1. Then, only the radical polymerizable monomer in the example 1 was replaced with the radical polymerizable monomer shown in FIGS. 7 and 8. Then the holographic recording media 40 thus produced were evaluated.

As a result, the volumetric shrinkage of the test pieces due to recording was 0.3% or less, and the M/# of the test pieces after being cured at 80° C. for one month was 4 or more, thereby yielding a good holographic recording media 40.

### Example 25

8.07 g of 1,6-hexanediol diglycidyl ether (epoxy equivalent: 151) employed as the epoxy compound and 0.529 g of the radical polymerizable monomer (final concentration 5 wt %) were mixed with each other, and stirred to provide a uniform monomer solution.

0.042 g of a photo-radical polymerization initiator and 1.93 g of diethylene triamine as a cure agent were added to the monomer solution, and stirred to dissolve. As the radical polymerizable monomer, 2VDbt of the compound 1 was employed. As the photo-radical polymerization initiator, bis(.eta.5-2,4-cylcopentadien-1-yl)-bis(2,6-difluoro-3-(1H-pyrrol-1-yl)-phenyl) titanium was employed. Finally, the solution was subjected to defoaming to obtain a raw material solution for the recording layer 20.

A spacer 30 made of a Teflon (registered trademark) sheet was disposed between a pair of glass plates to provide a space, and the above-mentioned raw material solution for the recording layer 20 was poured into the space. The resultant whole structure mentioned above was cured at room temperature (25° C.) for 24 hours under a light-shielded condition to obtain a test piece of the holographic recording medium 40 with a 200-μm thick recording layer. Then, the diffraction efficiency η of the holographic recording medium 40 was measured to determine the M/# and the volumetric shrinkage.

As a result, the volumetric shrinkage of the test piece due to recording was 0.3% or less, and the M/# of the test piece after being cured at 80° C. for one month was 4 or more, thereby yielding a good holographic recording medium.

### Examples 26 to 40

The radical polymerizable monomer, the epoxy monomer, and the photo-radical polymerization initiator were replaced with the radical polymerizable monomer shown in FIGS. 9 and 10. Then, the holographic recording media 40 thus produced were evaluated.

As a result, the volumetric shrinkage of the test piece due to recording was 0.3% or less, and the M/# of the test piece after being cured at 80° C. for one month was 4 or more, thereby yielding a good holographic recording medium.

The measurements of comparative examples 1 to 8 are shown below in FIG. 10.

### Comparative Examples 1 to 3

A test piece of recording medium was made using the same method as that in the example 1, except replacing the radical polymerizable monomer with 9-vinylcarbazole (9VCbz) or 2-vinylnaphthalene (2VNp). Then the diffraction efficiency η thereof was measured to determine the M/# and the volumetric shrinkage.

In the comparative example 1, when 9-vinylcarbazole (9VCbz) was employed as a photo-radical polymerization initiator, the test piece of recording medium became cloudy probably because of cationic polymerization of 9VCbz at the time of producing the test piece, thereby making it impossible to optically measure.

In the comparative example 2, the volumetric shrinkage of the test piece due to recording was 0.3% or less, and the M/# of the test piece after being cured at 80° C. for one month was 4 or more.

In the comparative example 3, the volumetric shrinkage of the test piece due to recording was 0.3% or more, and the M/# of the test piece after being cured at 80° C. for one month was 4 or more.

### Comparative Examples 4 to 8

A test piece of recording medium was made using the same method as that in the example 25, except replacing the radical polymerizable monomer with 9-vinylcarbazole (9VCbz) or 2-vinylnaphthalene (2VNp). Then the diffraction efficiency η thereof was measured to determine the M/# and the volumetric shrinkage.

In the comparative examples 6 and 8, when 9-vinylcarbazole (9VCbz) was employed as a photo-radical polymerization initiator, it was possible to produce a test piece of recording medium including a 5 wt % radical polymerizable monomer. However, a test piece of recording medium including a 7 wt % radical polymerizable monomer became cloudy probably because of 2-vinylnaphthalene (2VNp) having low compatibility with the polymer matrix of a epoxy resin, thereby making it impossible to optically measure.

In the comparative examples 4, 5 and 7, the volumetric shrinkage of the test piece due to recording was 0.3% or more, and the M/# of the test piece after being cured at 80° C. for one month was 4 or more.

As mentioned above, employing the radical polymerizable monomers according to the present invention provides a holographic recording medium with a high M/# and low volumetric shrinkage which is more excellent than a conventional one produced employing 9-vinyl carbazole (9VCbz) or 2-vinylnaphthalene (2VNp). Also in an acceleration test due to heating for examining durability, the excellence of the holographic recording medium with a low degradation of the M/# and high durability can be confirmed. Furthermore, the holographic recording medium has high compatibility with the polymer matrix, and allows it to further increase the concentration of the radical polymerizable compound, thereby providing a sensitive and high-performance holographic recording medium with a high M/#.

What is claimed is:

1. A holographic recording medium, comprising a recording layer including a skeleton being expressed with the following general formula (1), 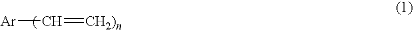
wherein
Ar represents a substituted or unsubstituted group selected from the following groups:
a benzothiophene group;
a naphthothiophene group;
a dibenzothiophene group;
a thienothiophene group;
a dithienobenzene group;
a benzothiazole group;
a naphthothiazole group;
a benzoisothiazole group;
a naphthoisothiazole group;
a phenothiazine group;
a phenoxathiin group;
a dithianaphthalene group;
a thianthrene group;
a thioxanthene group; and
a bithiophene group, and
wherein
n is an integer from 1 to 4.

2. The medium according to claim 1, wherein the recording layer further includes a polymerizable monomer.

3. The medium according to claim 1, wherein the general formula (1) represents one selected from the followings:
2-vinyldibenzothiophene;
2-vinylbenzothiophene;
4-vinyldibenzothiophene;
3-vinylbenzothiophene;
3-bromo-2-vinylbenzothiophene;
5-vinyl-2,2′-bithiophene;
5′-bromo-5-vinyl-2,2′-bithiophene;
6-vinylnaphtho[2,1-b]thiophene;
2-vinylthieno[3,2-b]thiophene;
2-vinylthieno[3,2-b]benzothiophene;
2-vinylthianthrene; and
2-vinylphenoxathiin.

4. The medium according to claim 2, wherein the general formula (1) represents one selected from the followings:
2-vinyldibenzothiophene;
2-vinylbenzothiophene;
4-vinyldibenzothiophene;
3-vinylbenzothiophene;
3-bromo-2-vinylbenzothiophene;
5-vinyl-2,2′-bithiophene;
5′-bromo-5-vinyl-2,2′-bithiophene;
6-vinylnaphtho[2,1-b]thiophene;
2-vinylthieno[3,2-b]thiophene;
2-vinylthieno[3,2-b]benzothiophene;
2-vinylthianthrene; and
2-vinylphenoxathiin.
